(19) United States
(12) Patent Application Publication
(10) Pub. No.: US 2026/0011639 A1
(43) Pub. Date: Jan. 8, 2026

(54) SEMICONDUCTOR DEVICE AND METHOD FOR MANUFACTURING THE SAME

(71) Applicant: Samsung Electronics Co., Ltd., Suwon-si (KR)

(72) Inventors: Minju KANG, Suwon-si, (KR); Hyunjin LEE, Suwon-si (KR); Yong Kwan KIM, Suwon-si (KR); Hui-Jung KIM, Suwon-si (KR); Inho CHA, Suwon-si (KR); Heejae CHAE, Suwon-si (KR)

(21) Appl. No.: 18/978,244

(22) Filed: Dec. 12, 2024

(30) Foreign Application Priority Data
Jul. 3, 2024 (KR) 10-2024-0087373

(51) Int. Cl. H01L 23/528; H10B 12/00

(52) U.S. Cl. CPC H01L 23/5283; H10B 12/482; H10B 12/488

(57) ABSTRACT

A semiconductor device includes a substrate, a bit line on the substrate extending in a first direction parallel to an upper surface of the substrate, a first semiconductor pattern and a second semiconductor pattern on the bit line, each extending in a second direction perpendicular to the upper surface of the substrate, and spaced apart from each other in the first direction, a word line between the first semiconductor pattern and the second semiconductor pattern extending in the second direction, a first connection structure on one end portion of the first semiconductor pattern, a second connection structure on one end portion of the second semiconductor pattern, a data storage pattern on each of the first connection structure and the second connection structure, and a gap between the first connection structure and the second connection structure.

### CROSS-REFERENCE TO RELATED APPLICATION

This U.S. non-provisional patent application claims priority under 35 U.S.C. § 119 of Korean Patent Application No. 10-2024-0087373, filed on Jul. 3, 2024, the entire contents of which are hereby incorporated by reference.

### BACKGROUND

The present disclosure herein relates to a semiconductor device, and more particularly, to a semiconductor device and a method for manufacturing the same.

Semiconductor devices are attracting attention as an important component in the electronics industry due to characteristics such as miniaturization, multi-functionality, and/or low manufacturing cost. The semiconductor device may be classified into a semiconductor memory device that stores logic data, a semiconductor logic device that calculates and processes the logic data, and a hybrid semiconductor device that includes a memory component and a logic component.

Recently, with a high speed and low power consumption of an electronic apparatus, a high operation speed and/or a low operation voltage are/is also required for the semiconductor device built therein. To satisfy such requirements, a more highly-integrated semiconductor device is needed. Accordingly, much research for improving integration of the semiconductor device is being conducted.

### SUMMARY

The present disclosure provides a semiconductor device with improved electrical characteristics and a method for manufacturing the same.

A technical goal of the inventive concept is not limited to the goal mentioned above, and other technical goals that are not mentioned may be clearly understood from description below by those skilled in the art.

An embodiment of the inventive concept provides a semiconductor device including a substrate, a bit line on the substrate extending in a first direction parallel to an upper surface of the substrate, a first semiconductor pattern and a second semiconductor pattern on the bit line, each extending in a second direction perpendicular to the upper surface of the substrate, and disposed spaced apart from each other in the first direction, a word line between the first semiconductor pattern and the second semiconductor pattern extending in the second direction, a first connection structure on one end portion of the first semiconductor pattern, a second connection structure on one end portion of the second semiconductor pattern, a data storage pattern on each of the first connection structure and the second connection structure, and a gap between the first connection structure and the second connection structure.

In an embodiment of the inventive concept, a semiconductor device includes a substrate, a bit line on the substrate extending in a first direction parallel to an upper surface of the substrate, a semiconductor pattern on the bit line extending in a second direction perpendicular to the upper surface of the substrate, a word line on side surfaces of the semiconductor pattern extending in the second, a data storage pattern on one end portion of the semiconductor pattern, a connection structure between the one end portion of the semiconductor pattern and the data storage pattern, and a gap at least partially surrounding a side surface of the connection structure.

In an embodiment of the inventive concept, a semiconductor device includes a substrate, a bit line on the substrate extending in a first direction parallel to an upper surface of the substrate, a first semiconductor pattern and a second semiconductor pattern on the bit line, each extending in a second direction perpendicular to the first direction, and spaced apart from each other in the first direction, a bit line contact between each of the first semiconductor pattern and the second semiconductor pattern, and the bit line, a first gate electrode extending between the first semiconductor pattern and the second semiconductor, a second gate electrode spaced apart from the first gate electrode in the first direction with the first semiconductor pattern therebetween, an upper surface of the second gate electrode being located closer to the substrate than an upper surface of the first gate electrode, a first connection structure on one end portion of the first semiconductor pattern, a second connection structure on one end portion of the second semiconductor pattern, a data storage pattern on each of the first connection structure and the second connection structure, and a gap between the first connection structure and the second connection structure.

### BRIEF DESCRIPTION OF THE FIGURES

The accompanying drawings are included to provide a further understanding of the inventive concept and are incorporated in and constitute a part of this specification. The drawings illustrate embodiments of the inventive concept and, together with the description, serve to explain principles of the inventive concept. In the drawings:

FIG. 1 is a block diagram illustrating a semiconductor device according to some embodiments of the inventive concept;

FIGS. 2 and 3 are respectively perspective views schematically illustrating a semiconductor device according to some embodiments of the inventive concept;

FIG. 4 is a plan view of a semiconductor device according to some embodiments of the inventive concept;

FIG. 5 is an enlarged view taken along portion ‘P1’ of FIG. 4;

FIGS. 6A, 6B, and 6C are cross-sectional views respectively taken along line A-A′, line B-B′, and line C-C′ of FIG. 4;

FIG. 7 is a cross-sectional view taken along line A-A′ of FIG. 4;

FIG. 8 is an enlarged view taken along portion ‘P1’ of FIG. 4;

FIGS. 9A and 9B are cross-sectional views respectively taken along line A-A′ and line B-B′ of FIG. 4;

FIG. 10 is a cross-sectional view taken along line A-A′ of FIG. 4;

FIG. 11 is an enlarged view taken along portion ‘P1’ of FIG. 4;

FIGS. 12A and 12B are cross-sectional views respectively taken along line A-A′ and line B-B′ of FIG. 4;

FIG. 13 is an enlarged view taken along portion ‘P1’ of FIG. 4;

FIG. 14 is a cross-sectional view taken along line A-A′ of FIG. 4;

FIG. 15 is an enlarged view taken along portion ‘P1’ of FIG. 4;

FIGS. 16A and 16B are cross-sectional views respectively taken along line A-A′ and line B-B′ of FIG. 4;

FIGS. 17A and 17B are cross-sectional views respectively taken along line A-A′ and line C-C′ of FIG. 4;

FIG. 18 is a plan view of a semiconductor device according to some embodiments of the inventive concept;

FIGS. 19A, 19B 19C are cross-sectional views each taken along line A-A′ of FIG. 18;

FIG. 20 is a cross-sectional view taken along line A-A′ of FIG. 18;

FIG. 21 is a cross-sectional view taken along line A-A′ of FIG. 18;

FIGS. 22, 23A, 23B, 24, 25A, 25B, 26A, and 26B are diagrams illustrating a method for manufacturing a semiconductor device according to some embodiments of the inventive concept;

FIGS. 27 to 31 are diagrams illustrating a method for manufacturing a semiconductor device according to some embodiments of the inventive concept;

FIGS. 32 and 33 are diagrams illustrating a method for manufacturing a semiconductor device according to some embodiments of the inventive concept;

FIGS. 34 to 36 are diagrams illustrating a method for manufacturing a semiconductor device according to some embodiments of the inventive concept;

FIGS. 37, 38A, 38B, 39, 40A, and 40B are diagrams illustrating a method for manufacturing a semiconductor device according to some embodiments of the inventive concept;

FIGS. 41A and 41B are diagrams illustrating a method for manufacturing a semiconductor device according to some embodiments of the inventive concept;

FIG. 42 is a diagram illustrating a method for manufacturing a semiconductor device according to some embodiments of the inventive concept;

FIGS. 43 and 44 are diagrams illustrating a method for manufacturing a semiconductor device according to some embodiments of the inventive concept;

FIG. 45 is a diagram illustrating a method for manufacturing a semiconductor device according to some embodiments of the inventive concept; and

FIGS. 46 and 47 are diagrams illustrating a method for manufacturing a semiconductor device according to some embodiments of the inventive concept.

### DETAILED DESCRIPTION

Hereinafter, embodiments of the inventive concept will be described with reference to the accompanying drawings in more detail to more specifically describe embodiments the inventive concept. The same reference numerals are given to the same elements in the drawings, and repeated descriptions thereof are omitted. As used herein, the term “and/or” includes any and all combinations of one or more of the associated listed items. It will be understood that when an element is referred to as being “on,” “attached” to, “connected” to, “coupled” with, “contacting,” etc., another element, it can be directly on, attached to, connected to, coupled with or contacting the other element or intervening elements may also be present. In contrast, when an element is referred to as being, for example, “directly on,” “directly attached” to, “directly connected” to, “directly coupled” with or “directly contacting” another element, there are no intervening elements present. It will be understood that, although the terms “first”, “second”, etc. may be used herein to describe various elements or components, these elements or components should not be limited by these terms. These terms are only used to distinguish one element or component from another element or component. Therefore, a first element or component discussed below could be termed a second element or component without departing from the technical spirits of the present disclosure. It is noted that aspects described with respect to one embodiment may be incorporated in different embodiments although not specifically described relative thereto. That is, all embodiments and/or features of any embodiments can be combined in any way and/or combination.

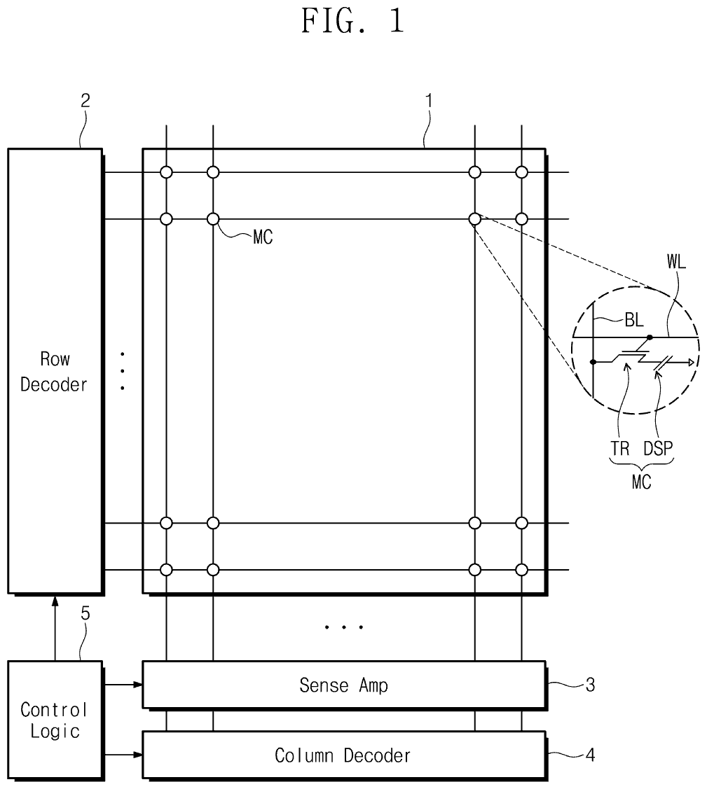

FIG. 1 is a block diagram illustrating a semiconductor device according to some embodiments of the inventive concept.

Referring to FIG. 1, the semiconductor device may include a memory cell array 1, a row decoder 2, a sense amplifier 3, a column decoder 4, and a control logic 5.

The memory cell array 1 may include a plurality of memory cells MC two-dimensionally or three-dimensionally arranged. Each of the memory cells MC may connect a word line WL and a bit line BL crossing each other. Each of the memory cells MC may include a selection element TR and a data storage element DSP. The selection element TR and the data storage element DSP may be electrically connected to each other. The selection element TR may be connected to all of the word line WL and the bit line BL. In other words, the selection element TR may be provided at a point at which the word line WL and the bit line BL cross each other.

The selection element TR may include a field effect transistor. The data storage element DSP may include a capacitor, a magnetic tunnel junction pattern, or a variable resistor. For example, a gate terminal of a transistor, which is the selection element TR, may be connected to the word line WL, and source/drain terminals of the transistor may be respectively connected to the bit line BL and the data storage element DSP.

The row decoder 2 may select any one of the word lines WL of the memory cell array 1 by decoding an address input from the outside thereof. The address decoded by the row decoder 2 may be supplied to a row driver (not shown), and the row driver may supply a predetermined voltage to a selected word line WL and unselected word lines WL in response to a control of control circuits.

The sense amplifier 3 may sense and amplify a voltage difference between a selected bit line BL and a reference bit line selected according to the address decoded by the column decoder 4, and may output the voltage difference.

The column decoder 4 may supply a data transmission path between the sense amplifier 3 and an external device (for example, a memory controller). The column decoder 4 may select any one of the bit lines BL by decoding an address input from the outside thereof. The control logic 5 may generate a control signal that controls an operation of writing a data to or reading a data from the memory cell array 1.

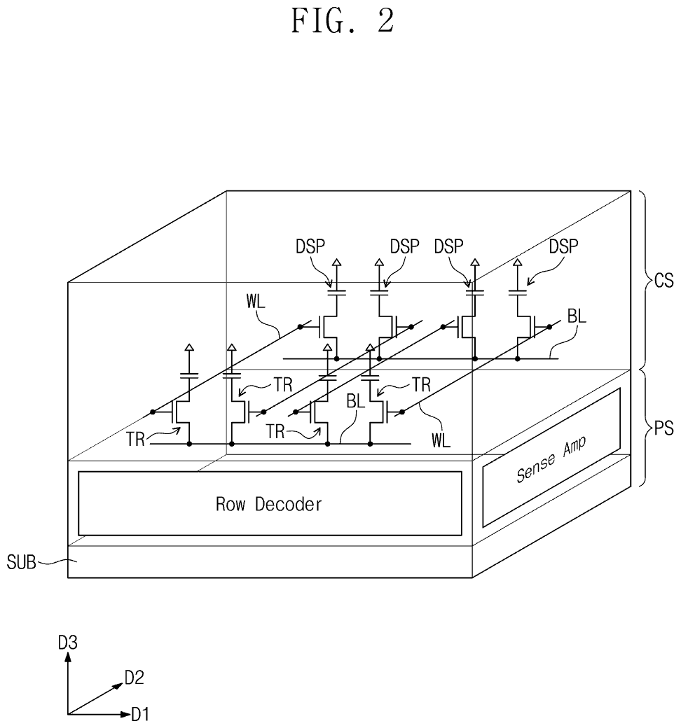

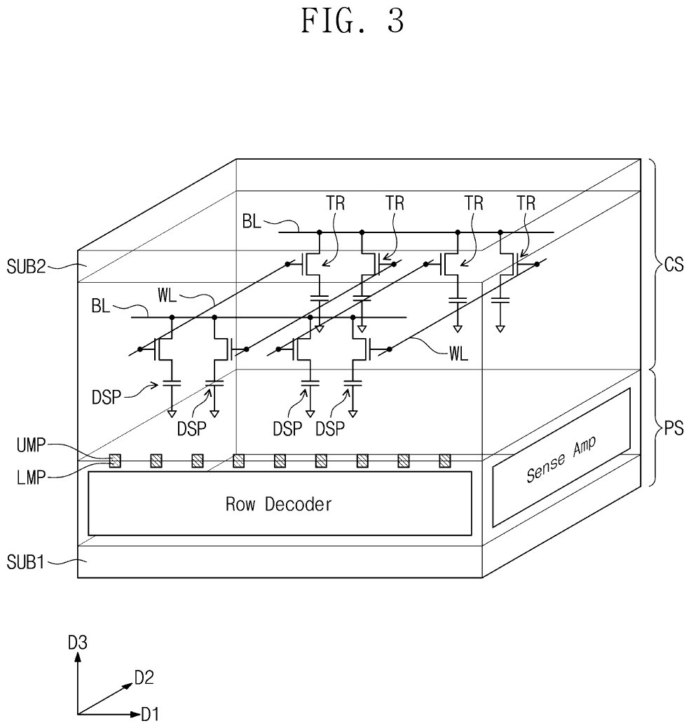

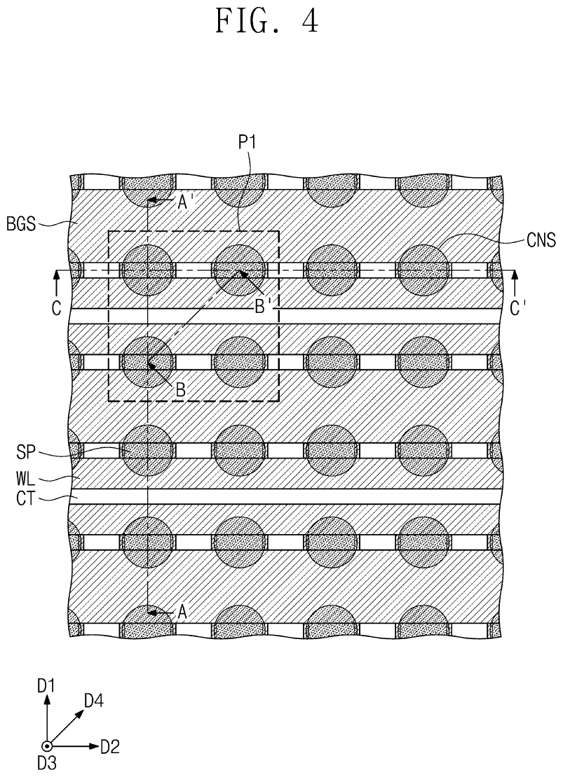

FIGS. 2 and 3 are respectively perspective views schematically illustrating a semiconductor device according to some embodiments of the inventive concept.

Referring to FIGS. 2 and 3, the semiconductor device may include a peripheral circuit structure PS on a substrate SUB, and a cell array structure CS connected to the peripheral circuit structure PS. The substrate SUB may have a form of a plate extending along a plane defined by a first direction D1 and a second direction D2. The first direction D1 and the second direction D2 may be parallel to an upper surface of the substrate SUB and may cross each other. A third direction D3 may be vertical to the upper surface of the substrate SUB, and may cross the first direction D1 and the second direction D2.

The peripheral circuit structure PS may include a core and peripheral circuits formed on the substrate SUB. The core and peripheral circuits may include the row and column decoders 2 and 4, the sense amplifier 3 and the control logics 5 described with reference to FIG. 1.

The cell array structure CS may include the memory cell array 1 (see FIG. 1) including the memory cells MC (see FIG. 1) two-dimensionally or three-dimensionally arranged. For example, the selection element TR (see FIG. 1) of each of the memory cells MC (see FIG. 1) may include a vertical channel transistor (VCT). The vertical channel transistor may include a channel of which a lengthwise direction is the third direction D3.

Referring to FIG. 2, the peripheral circuit structure PS may be provided on the substrate SUB. The cell array structure CS may be provided on the peripheral circuit structure PS. Although not shown, the peripheral circuit structure PS may be connected to the cell array structure CS through a separate contact.

Referring to FIG. 3, the semiconductor device may have a chip to chip (C2C) structure. The peripheral circuit structure PS may be provided on the substrate SUB1. First metal pads LMP may be provided on an upper portion of the peripheral circuit structure PS. The first metal pads LMP may be electrically connected to the core and peripheral circuits. The first metal pads LMP in the peripheral circuit structure PS may be bonded to second metal pads UMP, of the cell array structure CS, to be described later. Accordingly, the peripheral circuit structure PS and the cell array structure CS may be bonded to each other.

The cell array structure CS may be provided on a carrier substrate SUB2. The second metal pads UMP may be provided on a lower portion of the cell array structure CS. The second metal pads UMP may be electrically connected to the memory cell array 1 (see FIG. 1).

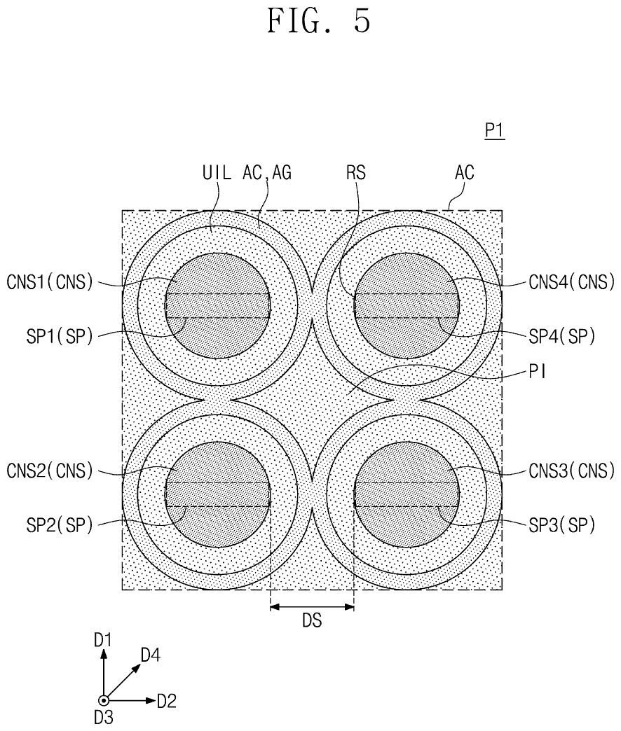

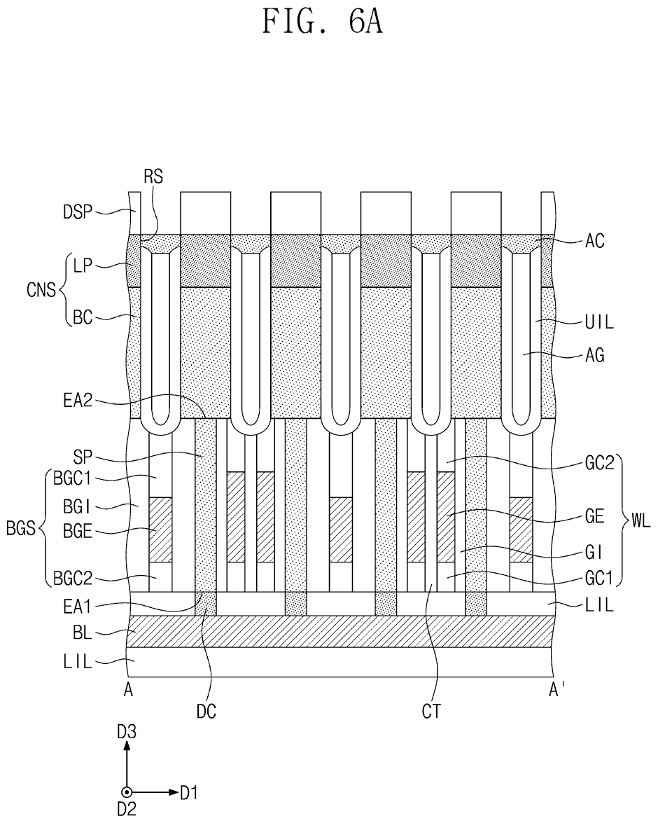

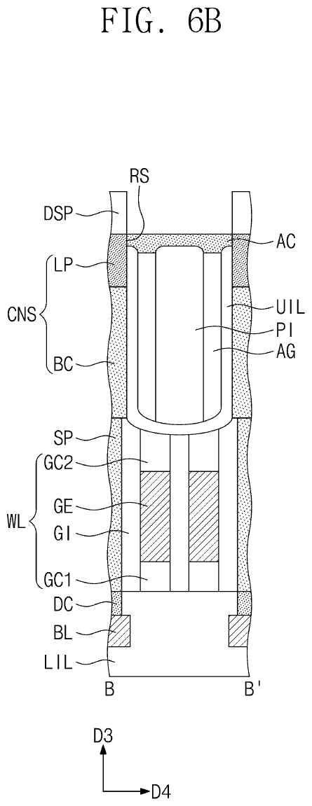

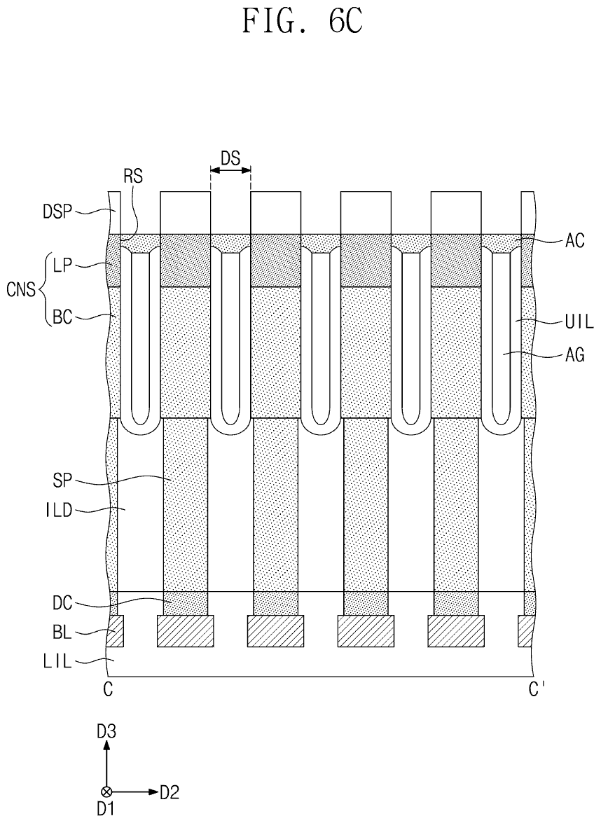

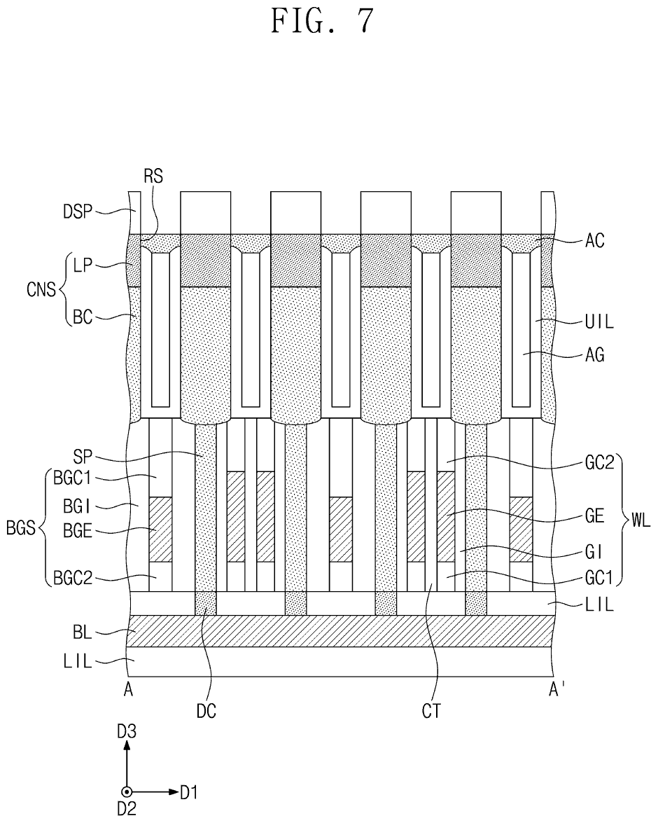

FIG. 4 is a plan view of a semiconductor device according to some embodiments of the inventive concept. FIG. 5 is an enlarged view taken along portion ‘P1’ of FIG. 4. FIGS. 6A to 6C are cross-sectional views respectively taken along line A-A′, line B-B′, and line C-C′ of FIG. 4.

Referring to FIGS. 4, 5, and 6A to 6C, FIGS. 4, 5, and 6A to 6C are plan views and cross-sectional views of components in the cell array structure CS described with reference to FIGS. 2 and 3.

The semiconductor device may include a lower insulating layer LIL. The lower insulating layer LIL may include an insulating material. For example, the lower insulating layer LIL may be provided on a lower portion of the cell array structure CS described with reference to FIG. 2. In this case, the lower insulating layer LIL may be adjacent to or in contact with the peripheral circuit structure PS described with reference to FIG. 2. In addition, the peripheral circuit structure PS described with reference to FIG. 2 may be interposed between the lower insulating layer LIL and the substrate SUB described with reference to FIG. 2. Moreover, the lower insulating layer LIL may include lines connected to the core and the peripheral circuits of the peripheral circuit structure PS described with reference to FIG. 2.

As another example, the lower insulating layer LIL may be provided on an upper portion of the cell array structure CS described with reference to FIG. 3 by flipping the cell array structure CS (see FIG. 2) of the semiconductor device. In this case, the lower insulating layer LIL may be adjacent to or in contact with the carrier substrate SUB2 described with reference to FIG. 3. The plan view and the cross-sectional view of a state in which the cell array structure CS (see FIG. 2) of the semiconductor device is not flipped are illustrated as diagrams, and the semiconductor device will be described with reference thereto, but an embodiment of the inventive concept is not limited thereto.

A bit line BL may be provided in the lower insulating layer LIL. The bit line BL may be provided on a first edge portion EA1 of a semiconductor pattern SP to be described later. The bit line BL may extend in the lower insulating layer LIL along the first direction D1. The bit line BL may include a conductive material. For example, the bit line BL may include at least one of a doped semiconductor material (for example, doped silicon, doped germanium, or the like), a metal material (for example, Ti, Mo, W, Cu, Al, Ta, Ru, Ir, Co, or the like), a metal silicide (for example, a silicide of Ti, Mo, W, Cu, Al, Ta, Ru, Ir, Co, or the like), or a metal nitride (for example, a nitride of Ti, Mo, W, Cu, Al, Ta, Ru, Ir, Co, or the like). The bit line BL may be a single film or composite film. The bit line BL may be provided in plurality. The bit lines BL may be disposed spaced apart from each other along the second direction D2.

A bit line contact DC may be provided in the lower insulating layer LIL. The bit line contact DC may be provided on the bit line BL. The bit line contact DC may be interposed between the bit line BL and the first edge portion EA1 of the semiconductor pattern SP to be described later. Accordingly, the bit line BL may be connected to the semiconductor pattern SP through the bit line contact DC. The bit line contact DC may include a conductive material. For example, the bit line contact DC may include doped silicon. The bit line contact DC may be provided in plurality. The bit line contacts DC may be disposed spaced apart from each other on one bit line BL along the first direction D1.

The semiconductor pattern SP may be provided on the bit line BL. For example, the semiconductor pattern SP may be provided on an upper surface of the bit line contact DC. The semiconductor pattern SP may extend on the bit line BL along the third direction D3. The semiconductor pattern SP may be provided in plurality. The semiconductor patterns SP may be disposed spaced apart from each other on one bit line BL along the first direction D1. The semiconductor patterns SP may be disposed spaced apart from each other along the second direction D2.

The semiconductor pattern SP may include a semiconductor material. For example, the semiconductor pattern SP may include at least one of silicon (for example, a single crystalline silicon), germanium, or silicon-germanium. For example, the semiconductor pattern SP may include an oxide semiconductor. In this case, the oxide semiconductor may include at least one of InGaZnO, InGaSiO, InSnZnO, InZnO, ZnO, ZnSnO, ZnON, ZrZnSnO, SnO, HfInZnO, GaZnSnO, AlZnSnO, YbGaZnO or InGaO, but an embodiment of the inventive concept is not limited thereto. For example, the semiconductor pattern SP may include indium gallium zinc oxide (IGZO). For example, the semiconductor pattern SP may include a two-dimensional semiconductor material. In this case, the two-dimensional semiconductor material may include graphene, carbon nanotube, or a combination thereof.

A word line WL may be provided on side surfaces of the semiconductor pattern SP. The word line WL may be interposed between the semiconductor patterns SP adjacent to each other in the first direction D1. The word line WL may extend along the second direction D2. The word line WL may be provided in plurality. The word lines WL may be disposed spaced apart from each other along the first direction D1. For example, a pair of word lines WL adjacent to each other in the first direction D1 may be interposed between the semiconductor patterns SP adjacent to each other in the first direction D1. For example, the pair of word lines WL adjacent to each other in the first direction D1 may be spaced apart from each other with a cutting pattern CT therebetween to be described later.

The word line WL may include a gate electrode GE extending along the second direction D2 and the third direction D3, a gate insulating pattern GI between the semiconductor pattern SP and the gate electrode GE, a first gate capping pattern GC1 on a lower surface of the gate electrode GE, and a second gate capping pattern GC2 on an upper surface of the gate electrode GE. The gate electrode GE may include a conductive material. For example, the gate electrode GE may include at least one of a metal material (for example, Ti, Mo, W, Cu, Al, Ta, Ru, Ir, Co, or the like), a metal silicide (for example, a silicide of Ti, Mo, W, Cu, Al, Ta, Ru, Ir, Co, or the like), or a metal nitride (for example, a nitride of Ti, Mo, W, Cu, Al, Ta, Ru, Ir, Co, or the like). For example, the gate insulating pattern GI may include at least one of silicon oxide or a high dielectric material. In the present disclosure, the high dielectric material is defined as a material having a higher dielectric constant than silicon oxide. The first gate capping pattern GC1 and the second gate capping pattern GC2 may each include an insulating material.

The cutting pattern CT may be interposed between the word lines WL adjacent to each other in the first direction D1, or may space the word lines WL apart from each other. The cutting pattern CT may extend along the third direction D3. For example, the cutting pattern CT may include an insulating material.

A back-gate structure BGS may be provided on a side surface of the semiconductor pattern SP. The back-gate structure BGS may be interposed between the semiconductor patterns SP adjacent to each other in the first direction D1. The back-gate structure BGS and the word line WL may be spaced apart from each other in the first direction D1 with the semiconductor pattern SP therebetween. The back-gate structure BGS may extend, along the second direction D2, between the semiconductor patterns SP adjacent to each other in the first direction D1. The back-gate structure BGS may be provided in plurality. The back-gate structures BGS may be disposed spaced apart from each other along the first direction D1.

Since the back-gate structure BGS is provided, a threshold voltage of a transistor including the semiconductor pattern SP may be controlled by a voltage applied to the back-gate structure BGS. Accordingly, controlling the threshold voltage through the back-gate structure BGS may be easier than controlling the threshold voltage by injecting an impurity into the semiconductor pattern SP. The threshold voltage may be controlled through the back-gate structure BGS to prevent unnecessary turning-on of the transistor.

The back-gate structure BGS may include a back-gate electrode BGE, a first back-gate capping pattern BGC1 on an upper surface of the back-gate electrode BGE, a second back-gate capping pattern BGC2 on a lower surface of the back-gate electrode BGE, and a back-gate insulating pattern BGI on and at least partially covering side surfaces thereof. For example, the back-gate electrode BGE may include at least one of a metal material (for example, Ti, Mo, W, Cu, Al, Ta, Ru, Ir, Co, or the like), a metal silicide (for example, a silicide of Ti, Mo, W, Cu, Al, Ta, Ru, Ir, Co, or the like), or a metal nitride (for example, a nitride of Ti, Mo, W, Cu, Al, Ta, Ru, Ir, Co, or the like). For example, the first and second back-gate capping patterns BGC1 and BGC2 may each include an insulating material. For example, the back-gate insulating pattern BGI may include at least one of silicon oxide or a high dielectric material.

An interlayer insulating layer ILD may be provided on the lower insulating layer LIL. The interlayer insulating layer ILD may be interposed between the semiconductor patterns SP adjacent to each other in the second direction D2. For example, the interlayer insulating layer ILD may include an insulating material.

A connection structure CNS may be provided on a second edge portion EA2 of the semiconductor pattern SP. The connection structure CNS may be connected to the bit line BL through the semiconductor pattern SP. The connection structure CNS may be provided in plurality. The connection structures CNS may be disposed spaced apart from each other in the first direction D1 and the second direction D2. In a plan view, the connection structures CNS may have a matrix form, but an embodiment of the inventive concept is not limited thereto. In a plan view, the connection structures CNS may be arranged in various forms such as a zigzag form, or a honeycomb form.

The connection structure CNS may include a storage node contact BC and a landing pad LP sequentially provided on the second edge portion EA2 of the semiconductor pattern SP. The storage node contact BC and the landing pad LP may vertically overlap each other. Side surfaces of the storage node contact BC and side surfaces of the landing pad LP may be aligned with each other. For example, the storage node contact BC and the landing pad LD may include a conductive material. For example, the storage node contact BC and the landing pad LP may each include at least one of a doped semiconductor material (for example, doped silicon, doped germanium, or the like), a metal material (for example, Ti, Mo, W, Cu, Al, Ta, Ru, Ir, Co, or the like), a metal silicide (for example, a silicide of Ti, Mo, W, Cu, Al, Ta, Ru, Ir, Co, or the like), or a metal nitride/(for example, a nitride of Ti, Mo, W, Cu, Al, Ta, Ru, Ir, Co, or the like).

A recess RS may be defined between the connection structures CNS. An upper portion of each of the first back-gate capping pattern BGC1 and the cutting pattern CT may be recessed to a predetermined depth by the recess RS.

An upper insulating layer UIL may conformally cover at least a portion of the recess RS. The upper insulating layer UIL may conformally cover at least a portion of side surfaces of each of the connection structures CNS. The upper insulating layer UIL may at least partially surround the side surfaces of each of the connection structures CNS. The upper insulating layer UIL may be on and cover at least a portion of an upper surface of the first back-gate capping pattern BGC1 and the cutting pattern CT. An upper surface of the upper insulating layer UIL may be located at a lower level than an upper surface of the connection structure CNS. A lower surface of the upper insulating layer UIL may be located at a lower level than a lower surface of the storage node contact BC and an upper surface of the semiconductor pattern SP. For example, the upper insulating layer UIL may include an insulating material (for example, SiN, SiOC, SiOCN, SiCN, SiBN, or the like).

A capping pattern AC may be on and at least partially cover side surfaces of each the connection structures CNS. Specifically, one capping pattern AC may at least partially surround and cover side surfaces of an upper portion of each of the connection structures CNS. The capping pattern AC may be provided on the upper surface of the upper insulating layer UIL, and may be in contact with the upper surface of the upper insulating layer UIL. For example, the upper surface of the capping pattern AC may be substantially coplanar with an upper surface of the connection structure CNS (in other words, an upper surface of the landing pad LP). For example, the capping pattern AC may include an insulating material (for example, SiN, SiOC, SiOCN, SiCN, SiBN, or the like).

A pillar pattern PI may be provided on side surfaces of the connection structure CNS. Specifically, the pillar pattern PI may extend from a lower portion of the recess RS to a lower surface of the capping pattern AC along the third direction D3. The pillar pattern PI may vertically overlap the capping pattern AC. For example, the pillar pattern PI may be inserted into the inside of the capping pattern AC. Accordingly, the lower surface of the capping pattern AC may be concave in the third direction D3. The pillar pattern PI may be in contact with a lower portion of the upper insulating layer UIL (in other words, a portion of the upper insulating layer UIL extending in a direction parallel to an upper surface of the substrate SUB). The pillar pattern PI may be spaced apart from an upper portion of the upper insulating layer UIL (in other words, the other portion of the upper insulating layer UIL extending in the third direction D3). For example, in a plan view, the pillar pattern PI may have a rhombus shape. For example, the pillar pattern PI may include an insulating material (for example, SiN, SiOC, SiOCN, SiCN, SiBN, or the like).

Referring to FIG. 5, the semiconductor pattern SP may include first to fourth semiconductor patterns SP1 to SP4, and the connection structure CNS may include first to fourth connection structures CNS1 to CNS4. The first to fourth connection structures CNS1 to CNS4 may be respectively provided on the first to fourth semiconductor patterns SP1 to SP4. The first semiconductor pattern SP1 may be spaced apart from the second semiconductor pattern SP2 in the first direction D1. The second semiconductor pattern SP2 may be spaced apart from the third semiconductor pattern SP3 in the second direction D2. The third semiconductor pattern SP3 may be spaced apart from the fourth semiconductor pattern SP4 in the first direction D1. The second semiconductor pattern SP2 may be spaced apart from the fourth semiconductor pattern SP4 in a fourth direction D4. The fourth direction D4 may be a direction parallel to the upper surface of the substrate SUB, and crossing the first direction D1 and the second direction D2. A separation direction of the first connection structure CNS1 to the fourth connection structure CNS4 may be the same as or similar to a separation direction between the first semiconductor pattern SP1 to the fourth semiconductor pattern SP4.

The pillar pattern PI may be interposed between the first connection structure CNS1 and the third connection structure CNS3. The pillar pattern PI may be interposed between the second connection structure CNS2 and the fourth connection structure CNS4.

Referring back to FIGS. 4, 5, and 6A to 6C, an air gap AG or gap may be provided on side surfaces of the connection structure CNS. In the present disclosure, the air gap AG may be defined by boundaries of solids, and may mean some region at least partially filled with a vapor-phase material, such as air. As another example, the air gap AG may mean an empty space. The air gap AG may be defined by the upper insulating layer UIL, the capping pattern AC, and the pillar pattern PI. For example, the air gap AG may have a dielectric constant of 0.

The air gap AG may be provided between the connection structures CNS. The air gap AG may be provided in the recess RS. The air gap AG may at least partially surround the side surfaces of each of the connection structures CNS. The air gap AG may extend along the side surfaces of the connection structure CNS in the third direction D3. For example, a width of the air gap AG may become smaller downward. For example, in a plan view, the air gap AG may have a ring shape.

The air gap AG may be provided between the connection structure CNS and the pillar pattern PI. The air gap AG may be provided between the upper insulating layer UIL and the pillar pattern PI. The air gap AG may be provided between the lower portion of the upper insulating layer UIL and the capping pattern AC. The air gap AG may be provided under the capping pattern AC. The air gap AG may at least partially surround side surfaces of the pillar pattern PI. The air gap AG may be provided between the capping pattern AC and the word line WL, and between the capping pattern AC and the back-gate structure BGS.

The upper portion of the upper insulating layer UIL may be interposed between the air gap AG and the connection structure CNS. The lower portion of the upper insulating layer UIL may be interposed between the air gap AG and the cutting pattern CT, and between the air gap AG and the first back-gate capping pattern BGC1.

The air gap AG may be connected to a lower surface of the capping pattern AC. The air gap AG may be connected to the upper insulating layer UIL. The air gap AG may be connected to side surfaces of the pillar pattern PI.

Side surfaces of the upper portion of the upper insulating layer UIL may be exposed by the air gap AG. In the present disclosure, the wording, “a surface is exposed by the air gap AG” may mean “a surface is exposed by the air gap AG so that the surface is in contact with a configuration, or is not covered by a configuration, i.e., is free of a configuration”. An upper surface of the lower portion of the upper insulating layer UIL may be partially exposed by the air gap AG. A lower surface of the capping pattern AC may be exposed by the air gap AG. Side surfaces of the pillar pattern PI may be exposed by the air gap AG.

Referring to FIG. 5, the air gap AG may be provided between the first connection structure CNS1 and the second connection structure CNS2, between the second connection structure CNS2 and the third connection structure CNS3, between the third connection structure CNS3 and the fourth connection structure CNS4, and between the first connection structure CNS1 and the fourth connection structure CNS4. The air gap AG may be interposed between each of the first to fourth connection structures CNS1 to CNS4 and the pillar pattern PI. The air gap AG may at least partially surround side surfaces of each of the first to fourth connection structures CNS1 to CNS4. An air gap AG at least partially surrounding the first connection structure CNS1, an air gap AG at least partially surrounding the second connection structure CNS2, an air gap AG at least partially surrounding the third connection structure CNS3, and an air gap AG at least partially surrounding the fourth connection structure CNS4 may be continuously connected to each other.

According to the inventive concept, the air gap AG may be interposed between the connection structures CNS. Accordingly, using the air gap AG in which a space between the connection structures CNS is not filled and remains empty may reduce capacitance unnecessarily formed between the adjacent connection structures CNS compared to completely filling the space between the connection structures CNS with an insulating material. As a result, disturbance caused by the adjacent connection structures CNS may be reduced. Accordingly, electrical characteristics of the semiconductor device may be improved.

In addition, the air gap AG may be interposed between the connection structures CNS so that a smaller separation distance DS between the connection structures CNS may be formed compared to completely filling the space between the connection structures CNS with an insulating material. Accordingly, a width of the connection structure CNS may be more widely formed, and a contact area between the connection structure CNS and the semiconductor pattern SP may be increased. Accordingly, electrical characteristics of the semiconductor device may be improved.

Referring back to FIGS. 4, 5, and 6A to 6C, a data storage pattern DSP may be provided on the connection structure CNS. The data storage pattern DSP may be connected to the semiconductor pattern SP through the connection structure CNS. The data storage pattern DSP may be provided in plurality. The data storage patterns DSP may be disposed spaced apart from each other in the first direction D1 and the second direction D2. The data storage pattern DSP may correspond to the data storage element DS described with reference to FIGS. 1 to 3.

The data storage pattern DSP may be a capacitor including, for example, a lower electrode, a dielectric film, and an upper electrode. In this case, the semiconductor device according to the inventive concept may be a dynamic random access memory (DRAM). As another example, the data storage patterns DSP may include a magnetic tunnel junction pattern. In this case, the semiconductor device according to the inventive concept may be a magnetic random access memory (MRAM). As another example, the data storage patterns DSP may include a phase-change material, or a variably resistive material. In this case, the semiconductor device according to the inventive concept may be a phase-change random access memory (PRAM), or a resistive random access memory (ReRAM). However, this is an example, and the inventive concept is not limited thereto. The data storage patterns DSP may include various structures and/or materials capable of storing a data.

Hereinafter, a semiconductor device according to some embodiments of the inventive concept will be described with reference to FIGS. 7 to 19. For simplification of description, duplicate description of that described above will be omitted, and a difference from that described above will be mainly described.

FIG. 7 is a cross-sectional view taken along line A-A′ of FIG. 4.

Referring to FIGS. 4 and 7, connection structures CNS may be formed through an engraving process, and features of the connection structure CNS according to that and peripheral configurations will be described.

Unlike what is described with reference to FIGS. 4, 5, and 6A to 6C, the upper portion of each of the cutting pattern CT and the first back-gate capping pattern BGC1 may not be recessed by the recess RS. Accordingly, a lower surface of the upper insulating layer UIL may have a substantially flat profile. The lower surface of the upper insulating layer UIL may be located at a higher level than an upper surface of the semiconductor pattern SP. The lower surface of the upper insulating layer UIL may be located at a higher level than a lower surface of the storage node contact BC.

The lower surface of the storage node contact BC may have a profile convex downward. Accordingly, an upper portion of the semiconductor pattern SP may be recessed to a predetermined depth. Similarly, an upper portion of each of the gate insulating pattern GI and the back-gate insulating pattern BGI may be recessed to a predetermined depth.

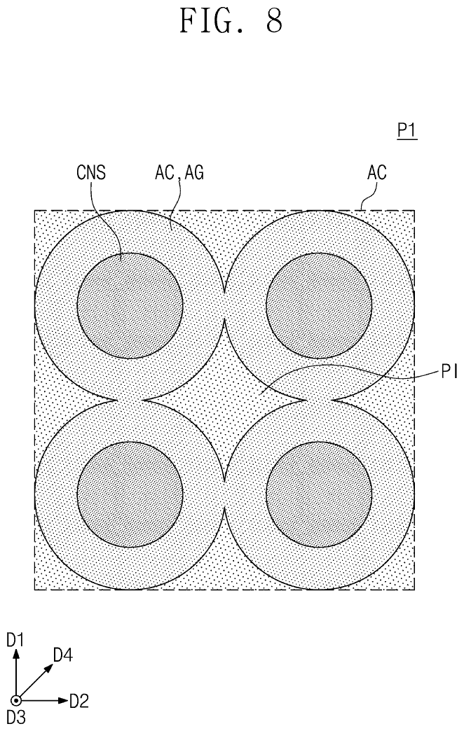

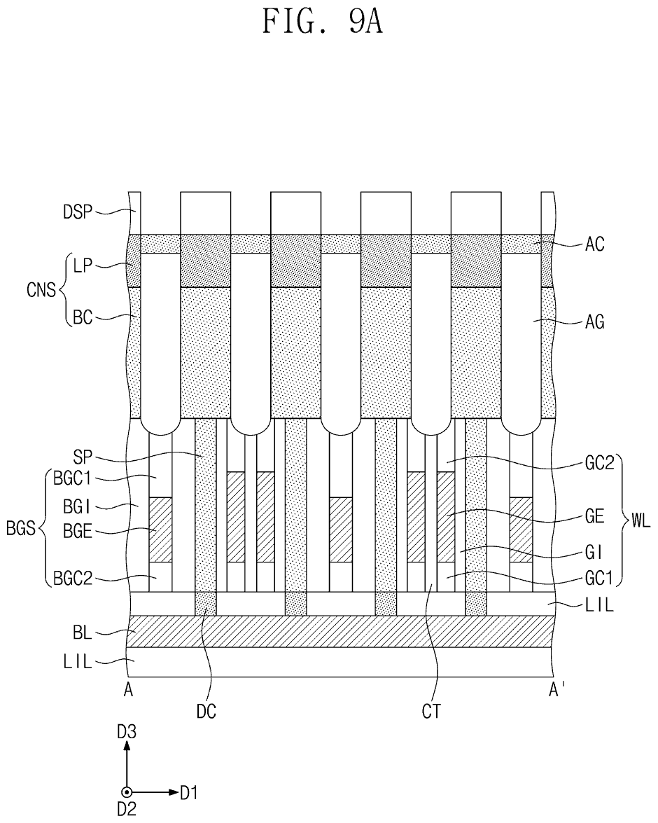

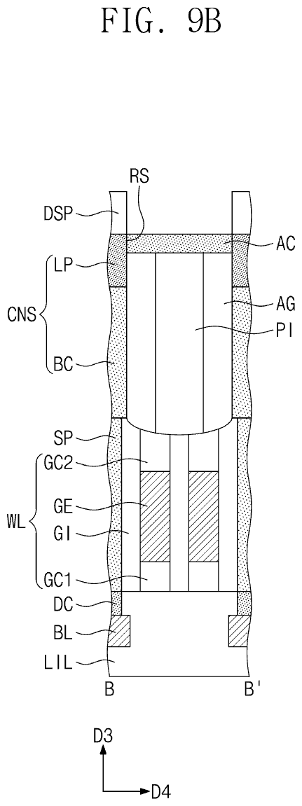

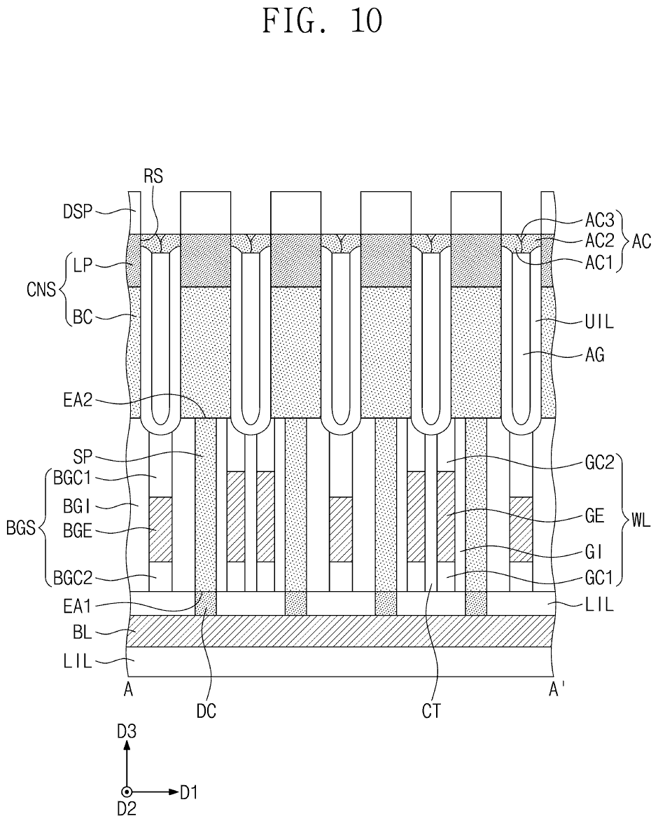

FIG. 8 is an enlarged view taken along portion ‘P1’ of FIG. 4. FIGS. 9A and 9B are cross-sectional views respectively taken along line A-A′ and line B-B′ of FIG. 4.

Referring to FIGS. 4, 8, 9A and 9B, the upper insulating layer UIL may not be provided. The air gap AG may be defined by the connection structures CNS, the capping pattern AC, and the pillar pattern PI. Side surfaces of the connection structure CNS may be connected to the air gap AG. The upper insulating layer UIL having a higher dielectric constant than the air gap AG may be substituted with the air gap AG to reduce the capacitance unnecessarily formed between the connection structures CNS, compared to providing the upper insulating layer UIL between the connection structures CNS. As a result, disturbance caused by the adjacent connection structures CNS may be reduced more, and electrical characteristics of the semiconductor device may be improved.

FIG. 10 is a cross-sectional view taken along line A-A′ of FIG. 4.

Referring to FIGS. 4 and 10, the capping pattern AC may include first to third capping patterns AC1, AC2, and AC3. The first capping pattern AC1 may be in contact with one connection structure CNS of a pair of connection structures CNS adjacent to each other. The second capping pattern AC2 may be in contact with another connection structure CNS of the pair of connection structures CNS adjacent to each other. The third capping pattern AC3 may be interposed between the first and second capping patterns AC1 and AC2.

Upper surfaces of the first to third capping patterns AC1, AC2, and AC3 may be coplanar with each other. A lower surface of each of the first and second capping patterns AC1 and AC2 may be exposed by the air gap AG.

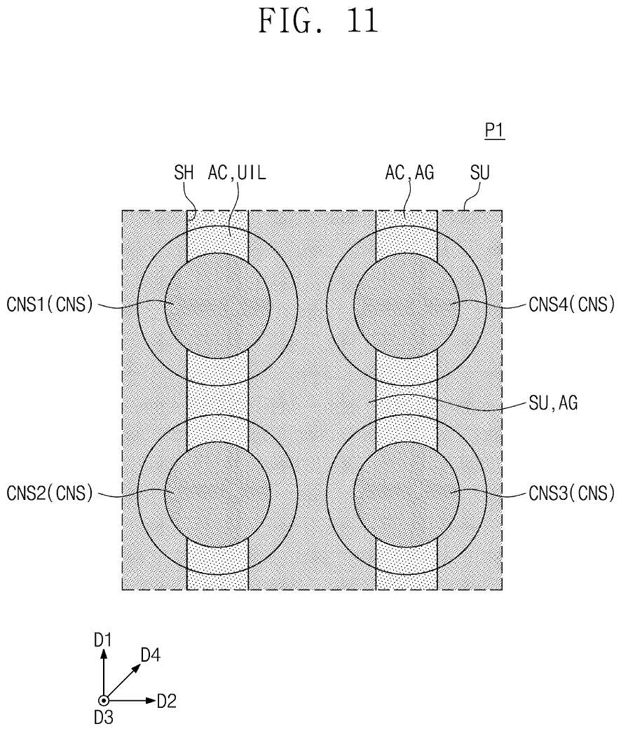

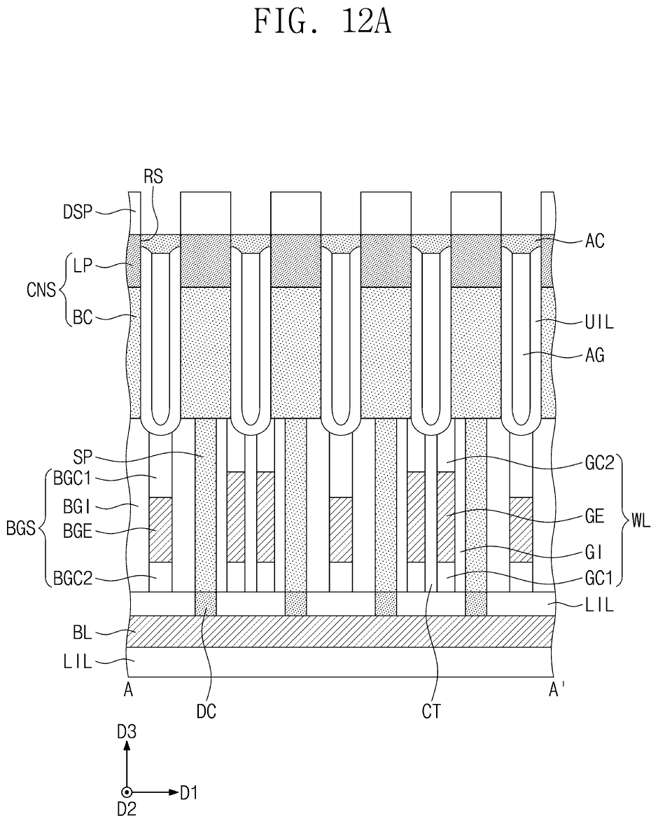

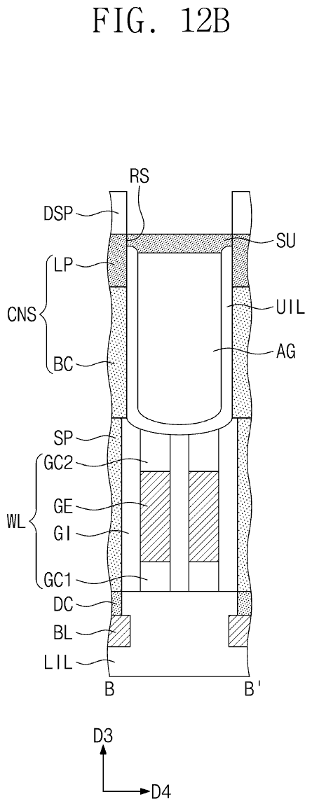

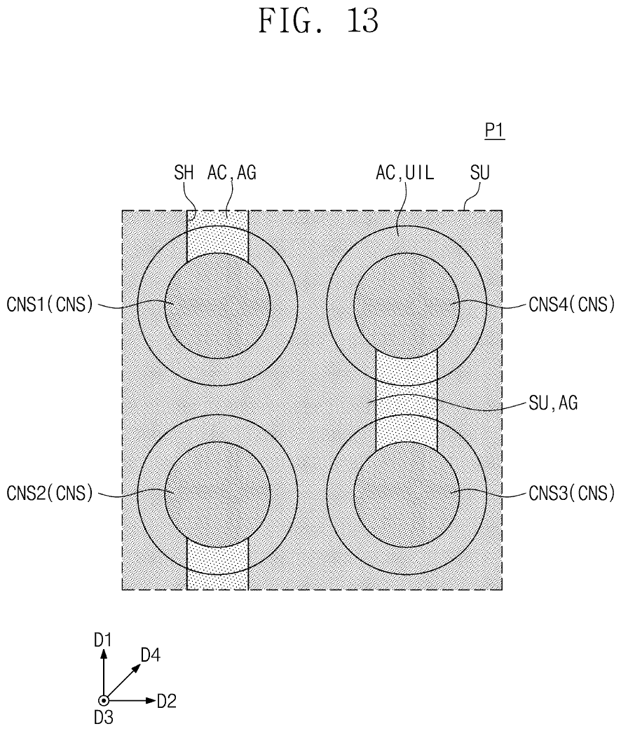

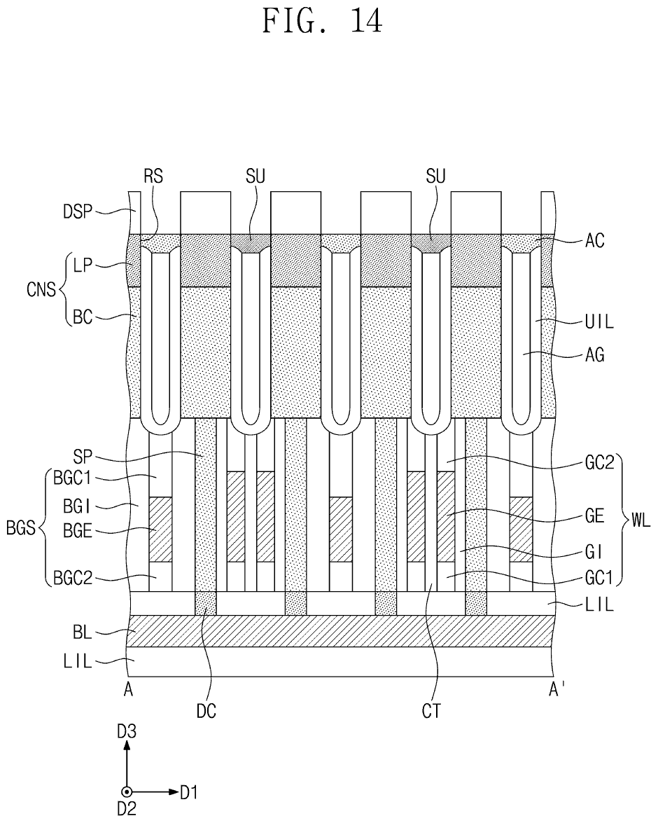

FIGS. 11 and 13 are enlarged views each taken along portion ‘P1’ of FIG. 4. FIGS. 12A and 12B are cross-sectional views respectively taken along line A-A′ and line B-B′ of FIG. 4. FIG. 14 is a cross-sectional view taken along line A-A′ of FIG. 4.

First, referring to FIGS. 4, 11, 12A and 12B, unlike what is described with reference to FIGS. 4, 5, and 6A to 6C, the capping pattern AC may not surround and cover the side surfaces of the connection structure CNS, and the pillar pattern PI may not be provided.

The capping pattern AC may be interposed between the connection structures CNS disposed spaced apart from each other in the first direction D1. For example, the capping pattern AC may be interposed between the first connection structure CNS1 and the second connection structure CNS2, and between the third connection structure CNS3 and the fourth connection structure CNS4. The capping pattern AC may be on and at least partially cover one side surface of the connection structure CNS. The capping pattern AC may be provided in plurality. The capping patterns AC may be disposed spaced apart from each other in the first direction D1 and the second direction D2.

A support pattern SU may be provided on side surfaces of the capping pattern AC. The support pattern SU may be in contact with the side surfaces of the capping pattern AC. The support pattern SU may be provided at the substantially same level as the capping pattern AC. The support pattern SU may partially cover side surfaces of each the connection structures CNS. A portion of an inner side surface of the support pattern SU may be no and at least partially cover the side surfaces of the connection structure CNS, and thus may be concave in the second direction D2 or an opposite direction of the second direction D2. The support pattern SU may be on and at least partially cover the upper surface of the upper insulating layer UIL. A lower surface of the support pattern SU may be partially exposed by the air gap AG. For example, the support pattern SU may include an insulating material. The air gap AG may be defined by the upper insulating layer UIL, the capping pattern AC, and the support pattern SU.

The support pattern SU may have a support hole SH inside thereof. The support hole SH may be provided in plurality. The support holes SH may be disposed spaced apart from each other in the first direction D1 and the second direction D2. The support holes SH may be provided between the connection structures CNS disposed spaced apart from each other in the first direction D1. The capping patterns AC may at least partially fill the insides of the support holes SH.

A method for arranging the support holes SH may be variously changed depending on those skilled in the art. Referring FIGS. 4, 13, and 14, in a plan view, the support holes SH may be arranged in a zigzag form. In other words, the support hole SH may be interposed between one connection structure CNS among the connection structures CNS, and another connection structure CNS adjacent to the one connection structure CNS in the first direction D1, but may not be interposed between the one connection structure CNS and another connection structure CNS adjacent to the one connection structure CNS in an opposite direction of the first direction D1. In FIG. 13, the support hole SH may be interposed between a first connection structure CNS1 and a connection structure CNS adjacent to the first connection structure CNS1 in the first direction D1, and between a second connection structure CNS2 and a connection structure CNS adjacent to the second connection structure CNS2 in the opposite direction of the first direction D1, but may not be interposed between the first connection structure CNS1 and the second connection structure CNS2. Accordingly, the support pattern SU may be interposed between the first connection structure CNS1 and the second connection structure CNS2.

In FIG. 13, the support hole SH may not be interposed between a fourth connection structure CNS4 and a connection structure CNS adjacent to the fourth connection structure CNS4 in the first direction D1, and between a third connection structure CNS3 and a connection structure CNS adjacent to the third connection structure CNS3 in the opposite direction of the first direction D1, but may be interposed between the third connection structure CNS3 and the fourth connection structure CNS4. Accordingly, the support pattern SU may be interposed between the fourth connection structure CNS4 and a connection structure CNS adjacent to the fourth connection structure CNS4 in the first direction D1, and between the third connection structure CNS3 and a connection structure CNS adjacent to the third connection structure CNS3 in the opposite direction of the first direction D1.

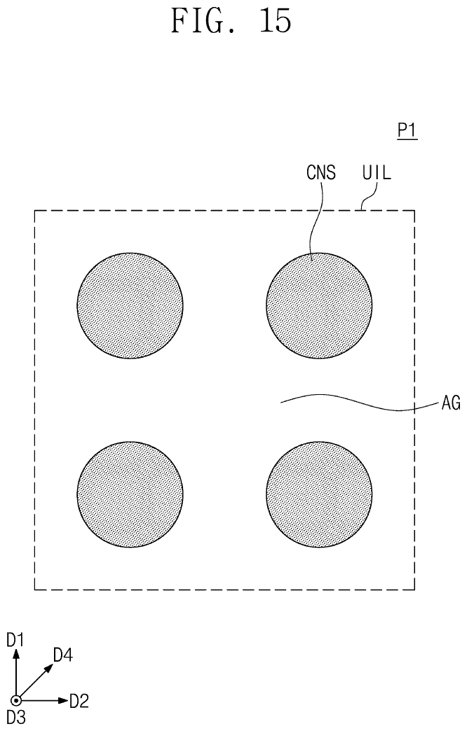

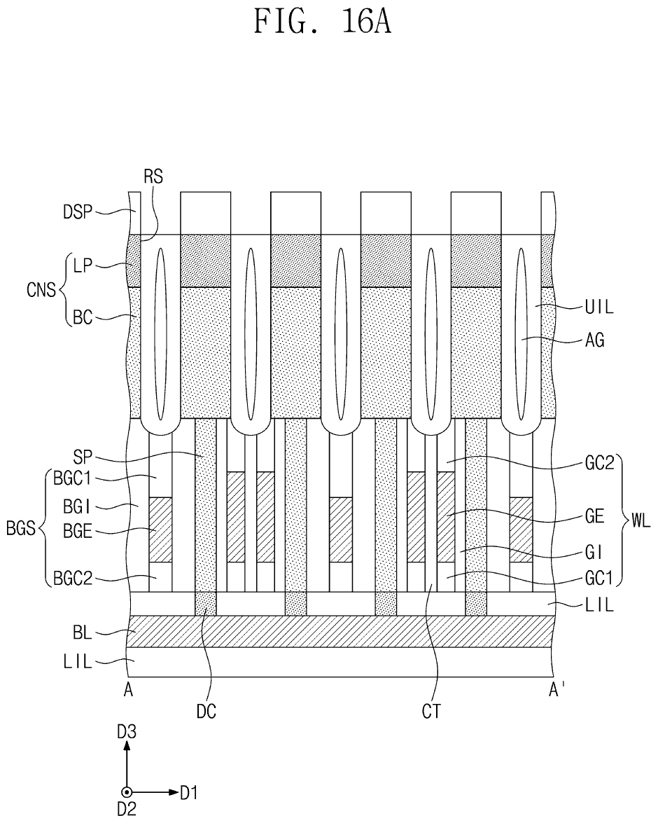

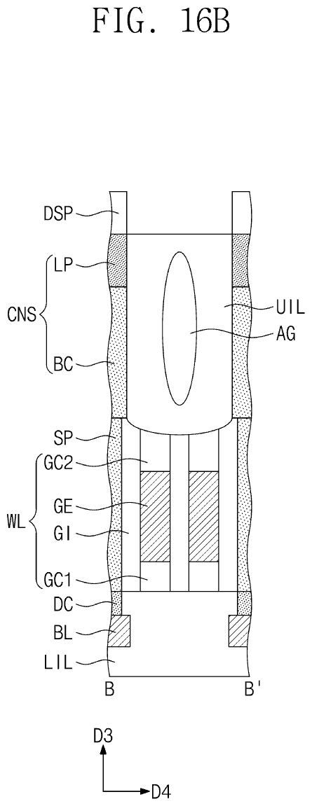

FIG. 15 is an enlarged view taken along portion ‘P1’ of FIG. 4. FIGS. 16A and 16B are cross-sectional views respectively taken along line A-A′ and line B-B′ of FIG. 4.

Referring to FIGS. 4, 15, 16A and 16B, the capping pattern AC and the pillar pattern PI may not be provided. The upper insulating layer UIL may at least partially fill a space between the connection structures CNS. The air gap AG may be provided inside the upper insulating layer UIL. The air gap AG may be defined by the upper insulating layer UIL. The air gap AG may be connected to an inner side surface of the upper insulating layer UIL.

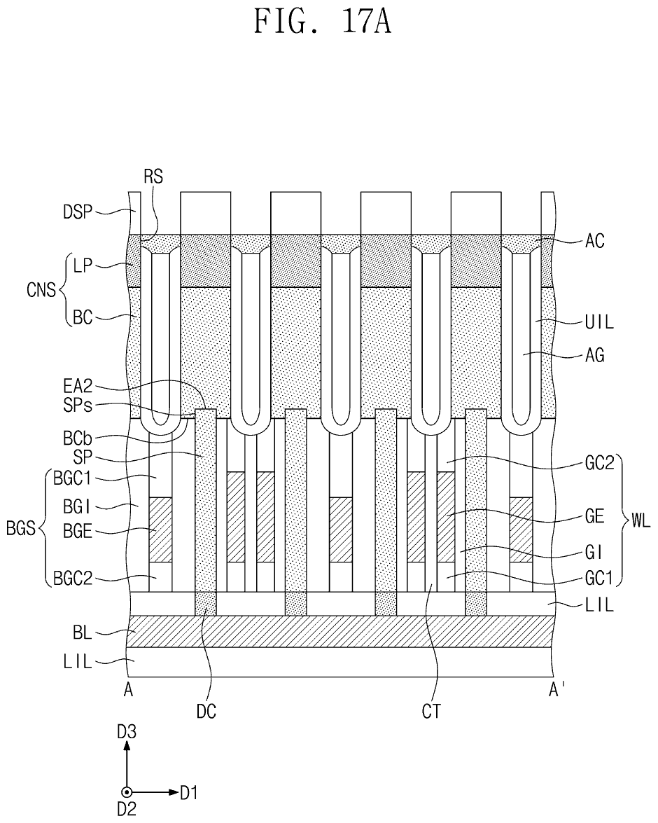

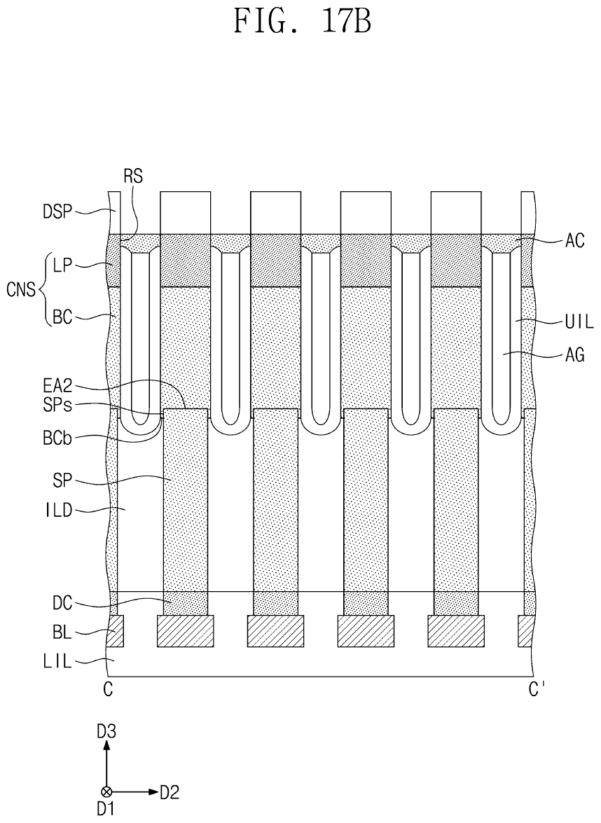

FIGS. 17A and 17B are cross-sectional views respectively taken along line A-A′ and line C-C′ of FIG. 4.

Referring to FIGS. 4, 17A, and 17B, the second edge portion EA2 of the semiconductor pattern SP may be inserted into the storage node contact BC. An upper surface (in other words, the second edge portion EA2) of the semiconductor pattern SP may be located at a higher level than a lower surface BCb of the storage node contact BC. Accordingly, the storage node contact BC may be on and at least partially cover not only the upper surface of the semiconductor pattern SP but also a portion of side surfaces SPs of the semiconductor pattern SP. As a result, a contact area between the storage node contact BC and the semiconductor pattern SP may be increased. Accordingly, electrical characteristics of the semiconductor device may be improved.

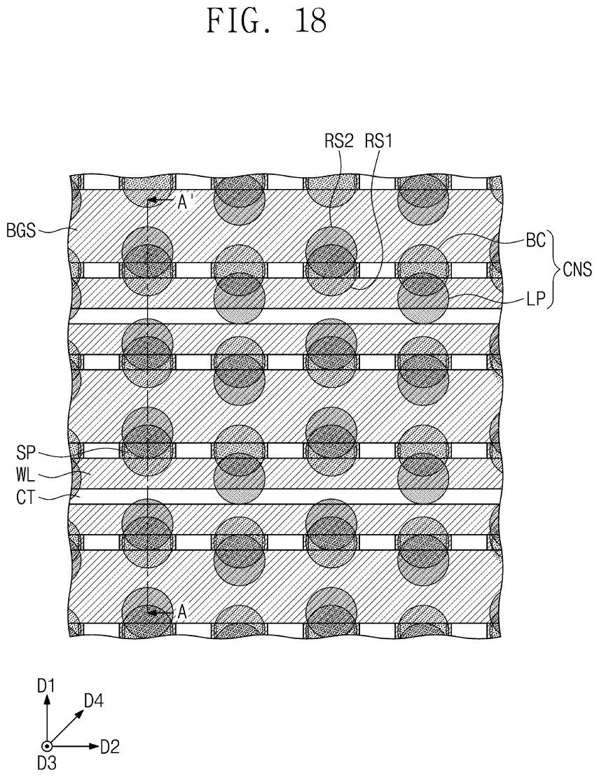

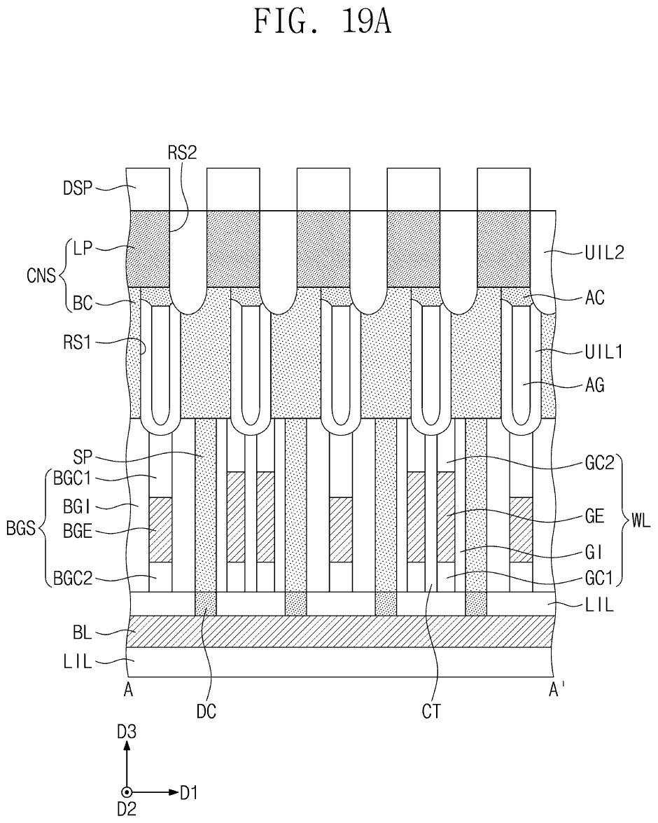

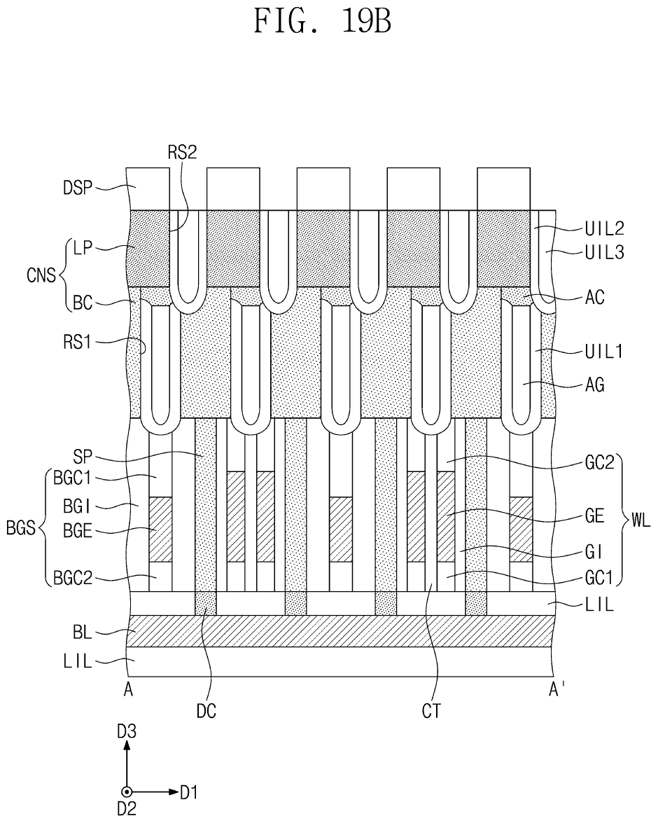

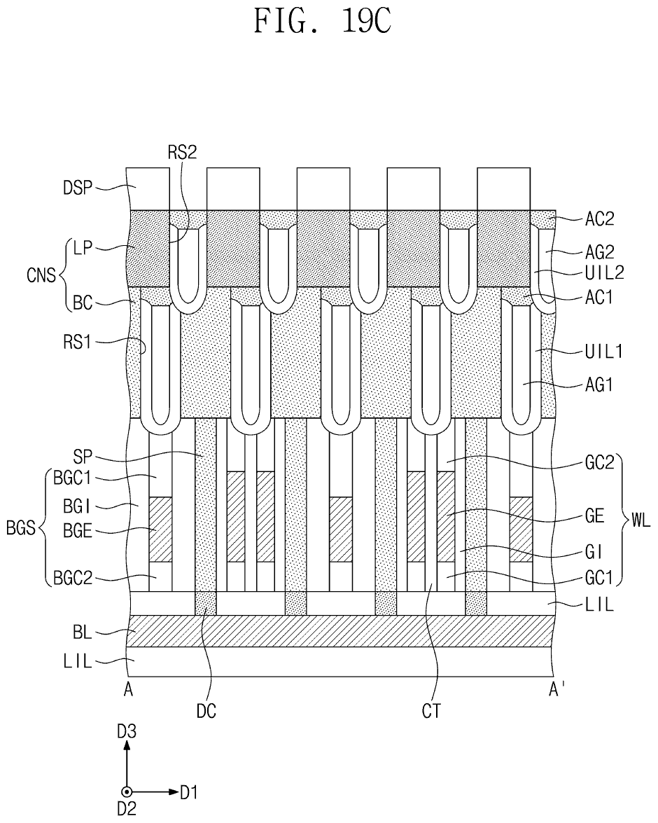

FIG. 18 is a plan view of a semiconductor device according to some embodiments of the inventive concept. FIGS. 19A to 19C are cross-sectional views each taken along line A-A′ of FIG. 18.

First, referring to FIGS. 18 and 19A, a first recess RS1 may be defined between the storage node contacts BC. An upper portion of each of the first back-gate capping pattern BGC1 and the cutting pattern CT may be recessed to a predetermined depth by the first recess RS1.

A first upper insulating layer UIL1 may conformally cover the first recess RS1. An upper surface of the capping pattern AC may be coplanar with an upper surface of the storage node contact BC. The air gap AG may be provided in the first recess RS1.

The storage node contact BC may have a matrix shape in a plan view. The landing pad LP may be offset from the storage node contact BC in the first direction D1 or the opposite direction of the first direction D1. Accordingly, the landing pads LP may have a honeycomb shape in a plan view.

A second recess RS2 may be defined between the landing pads LP. The first upper insulating layer UIL1, the storage node contact BC and the capping pattern AC may be each partially recessed to a predetermined depth by the second recess RS2.

A second upper insulating layer UIL2 may at least partially fill the second recess RS2. The second upper insulating layer UIL2 may at least partially surround and cover the landing pads LP. The landing pads LP may be spaced apart from each other by the second upper insulating layer UIL2. In a plan view, the second upper insulating layer UIL2 may have a mesh shape. For example, the second upper insulating layer UIL2 may include an insulating material.

A composition of the insulating material between the landing pad LP may be various. First, referring to FIGS. 18 and 19B, the second upper insulating layer UIL2 may conformally cover the second recess RS2. A third upper insulating layer UIL3 including an insulating material may at least partially fill a remaining portion of the second recess RS2.

Next, referring to FIGS. 18 and 19C, the capping pattern AC described with reference to FIGS. 18 and 19A may be a first capping pattern AC1. The air gap AG described with reference to FIGS. 18 and 19A may be a first air gap AG1. The second upper insulating layer UIL2 may conformally cover the second recess RS2. The second capping pattern AC2 may at least partially surround and cover side surfaces of upper portions of the landing pads LP. A second air gap AG2 may be provided between the landing pads LP. The second air gap AG2 may be provided between the second capping pattern AC2 and the second upper insulating layer UIL2.

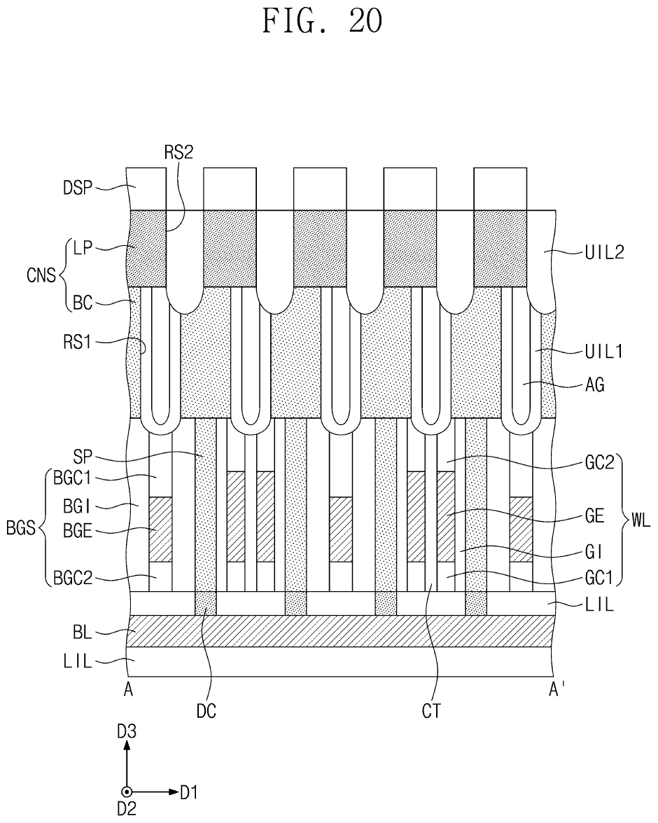

FIG. 20 is a cross-sectional view taken along line A-A′ of FIG. 18.

Referring to FIGS. 18 and 20, the capping pattern AC described with reference to FIGS. 18 and 19A may not be provided. An upper surface of the first upper insulating layer UIL1 may be substantially coplanar with an upper surface of the storage node contact BC. The air gap AG may be defined by the first upper insulating layer UIL1, the landing pad LP and the second upper insulating layer UIL2. A lower surface of each of the landing pads LP may be connected to the air gap AG. A lower surface of the second upper insulating layer UIL2 may be connected to the air gap AG.

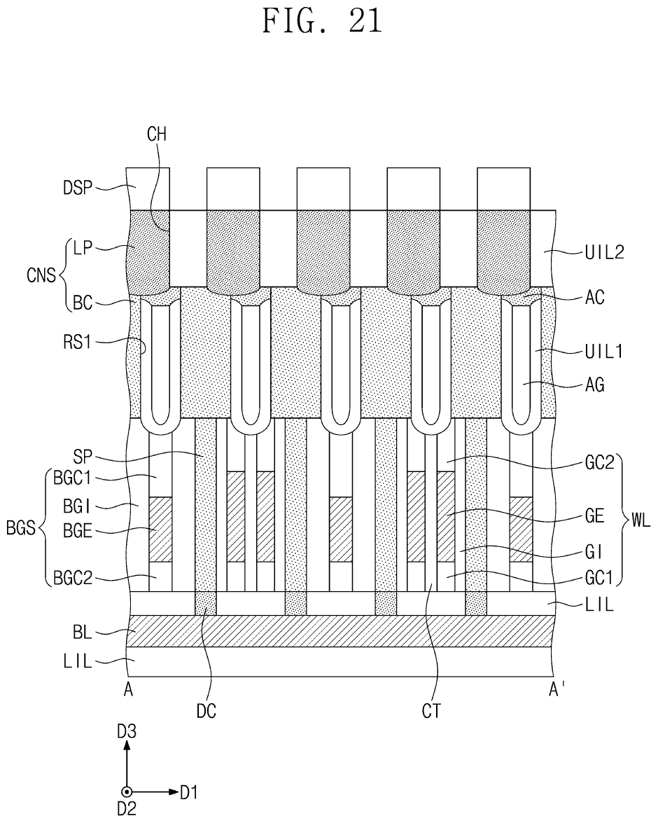

FIG. 21 is a cross-sectional view taken along line A-A′ of FIG. 18.

Referring to FIGS. 18 and 21, the landing pads LP may be formed through an engraving process, and features of the landing pads LP according to that and peripheral configurations will be described.

The lower surface of the second upper insulating layer UIL2 may have a substantially flat profile. The lower surface of the second upper insulating layer UIL2 may be located at a higher level than the lower surface of each of the landing pads LP.

The lower surface of the landing pad LP may have a profile convex downward. The lower surface of the landing pad LP may be located at a lower level than an upper surface of the capping pattern AC and an upper surface of the storage node contact BC.

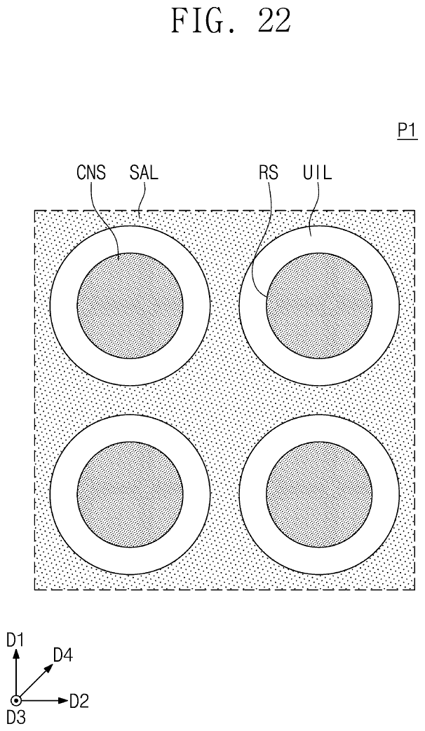

Hereinafter, a method for manufacturing a semiconductor device according to some embodiments of the inventive concept will be described with reference to FIGS. 22 to 47. For simplification of description, duplicate description of that described above will be omitted, and a difference from that described above will be mainly described.

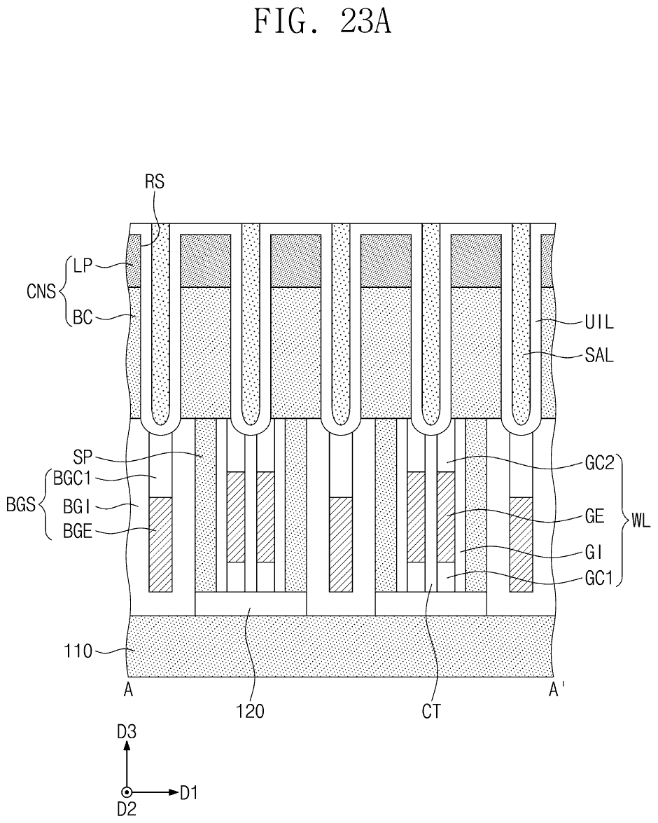

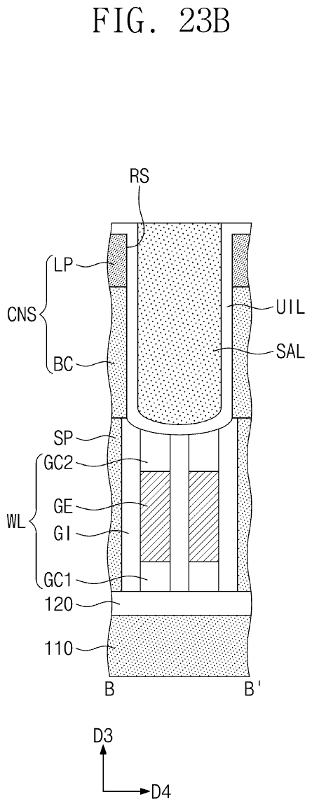

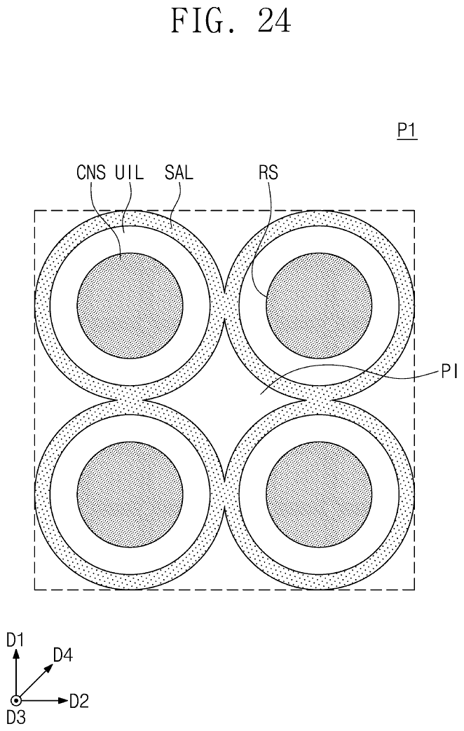

FIGS. 22 to 26B are diagrams illustrating a method for manufacturing a semiconductor device according to some embodiments of the inventive concept. Specifically, FIGS. 22 and 24 are enlarged views each taken along portion ‘P1’ of FIG. 4. FIGS. 23A, 25A, and 26A are cross-sectional views each taken along line A-A′ of FIG. 4. FIGS. 23B, 25B and 26B are cross-sectional views each taken along line B-B′ of FIG. 4.

Referring to FIGS. 4, 22, 23A and 23B, a first substrate 110 may be prepared. A dummy insulating film 120 and a second substrate not shown may be sequentially formed on the first substrate 110. For example, the first substrate 110 and the second substrate may include a semiconductor material. The dummy insulating film 120 may include an insulating material.

Thereafter, a first patterning process of the dummy insulating film 120 and the second substrate may be performed. Accordingly, each of the dummy insulating film 120 and the second substrate may be partially removed. A back-gate insulating pattern BGI, a back-gate electrode BGE and a first back-gate capping pattern BGC1 may be sequentially formed in a region in which the dummy insulating film 120 and the second substrate are removed.

Thereafter, a second patterning process of the second substrate may be performed. Accordingly, the second substrate may be partially removed. A word line WL and a cutting pattern CT may be formed in a region in which the second substrate is removed. The second substrate may be divided into a plurality of second substrates spaced apart from each other in the first direction D1 through the first and second patterning processes.

Thereafter, a third patterning process of the second substrate may be performed. Accordingly, the second substrate may be partially removed. An interlayer insulating layer ILD described with reference to FIG. 6C may be formed in a region in which the second substrate is removed. The second substrate may be divided into a plurality of semiconductor patterns SP spaced apart from each other in the second direction D2 through the third patterning process. Sequence of the first to third patterning processes may be variously disposed depending on those skilled in the art.

Connection structures CNS may be formed on upper surfaces of the semiconductor patterns SP. The connection structures CNS may be formed in an embossing process. In other words, forming the connection structures CNS may include entirely forming a storage node contact film (not shown) and a landing pad film (not shown) on the first substrate 110, and performing a process of removing each of the storage node contact film and the landing pad film to divide into a plurality of storage node contacts BC and a plurality of landing pads LP. A recess RS may be formed between the connection structures CNS through a process of forming the connection structures CNS.

An upper insulating layer UIL may be formed to conformally cover the recess RS. Thereafter, a sacrificial film SAL including an insulating material may be formed to at least partially fill a remaining portion of the recess RS.

Referring to FIGS. 4, 24, 25A and 25B, a process of partially removing the sacrificial film SAL may be performed. A pillar film (not shown) may be formed in a region in which the sacrificial film SAL is partially removed. The pillar film may be formed to be on and at least partially cover an upper surface of each of the sacrificial film SAL and the upper insulating layer UIL. Thereafter, a process of removing an upper portion of each of the sacrificial film SAL and the upper insulating layer UIL and an upper portion of the pillar film may be performed. Accordingly, the pillar film may be divided into a plurality of pillar patterns PI. An upper surface of the sacrificial film SAL may be exposed to the outside through the removing process.

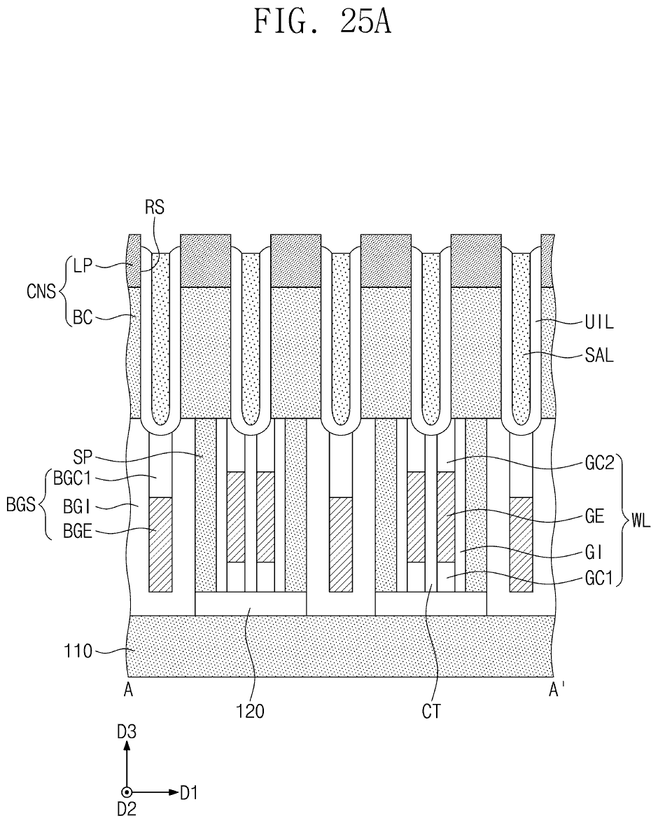

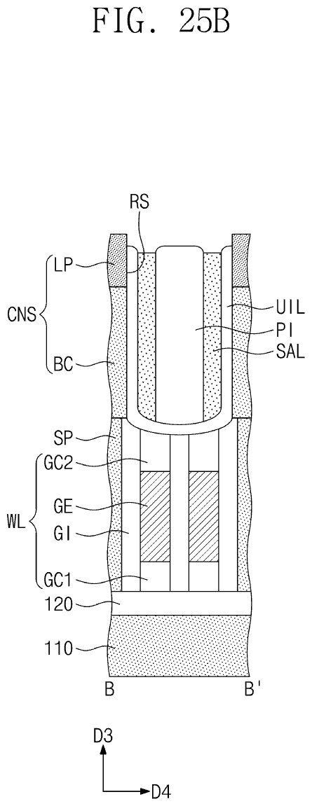

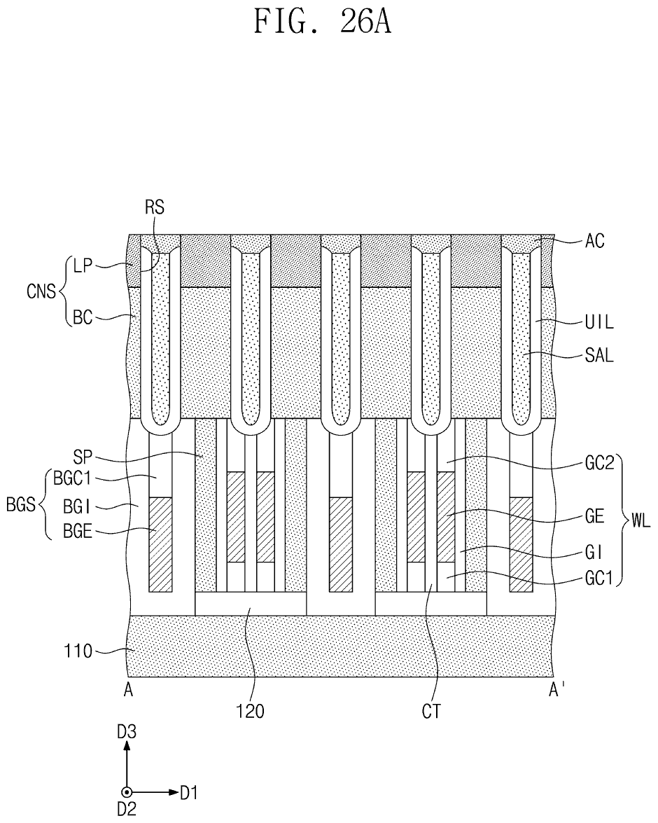

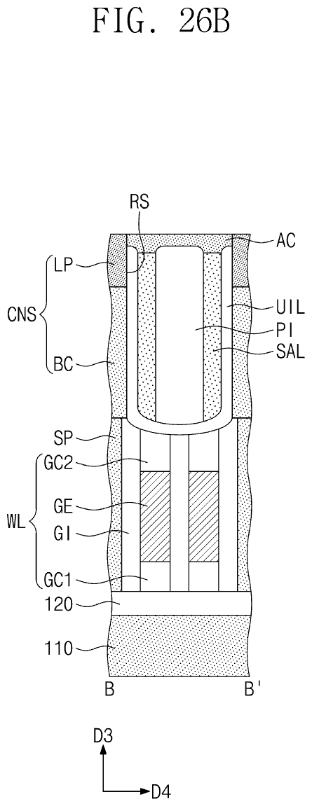

Referring to FIGS. 4, 26A, and 26B, the exposed sacrificial film SAL (see FIGS. 25A and 25B) may be removed. Accordingly, a region not filled with a solid material may be formed in the recess RS. Thereafter, the capping pattern AC may be formed to be on and at least partially cover upper surfaces of the upper insulating layer UIL and the pillar pattern PI. A region in which the sacrificial film SAL (see FIGS. 25A and 25b) is removed may become the region not filled with a solid material by at least partially filling the upper portion of the recess RS with the capping pattern AC. Accordingly, the air gap AG may be formed between the connection structures CNS.

Referring back to FIGS. 4, 5, and 6A to 6C, a data storage pattern DSP may be formed on the connection structure CNS.

Although not shown, the first substrate 110 (see FIGS. 25A and 25B) may be turned upside down. Accordingly, a lower surface of the first substrate 110 (see FIGS. 25A and 25B) may be exposed. The first substrate 110 (see FIGS. 25A, and 25B) and the dummy insulating film 120 (see FIGS. 25A and 25B) may be removed.

The back-gate electrode BGE may be partially removed, and a second back-gate capping pattern BGC2 may be formed in a region in which the back-gate electrode BGE is removed. Accordingly, the back-gate electrode BGE, the back-gate insulating pattern BGI, the first back-gate capping pattern BGC1 and the second back-gate capping pattern BGC2 may constitute a back-gate structure BGS.

A bit line contact DC may be formed on the semiconductor pattern SP. A bit line BL may be formed on the bit line contact DC. A lower insulating layer LIL may be formed to be on and at least partially cover the bit line contact DC and the bit line BL. The lower insulating layer LIL may be formed at various times regardless of forming the bit line contact DC and the bit line BL.

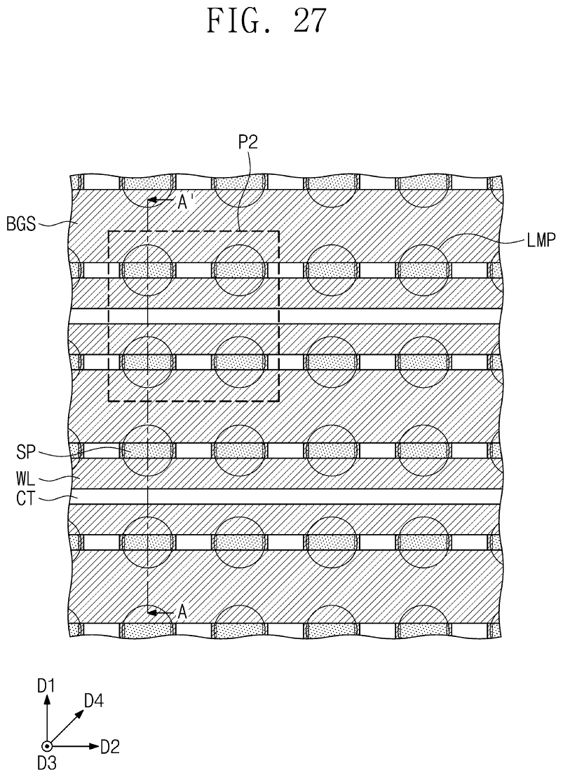

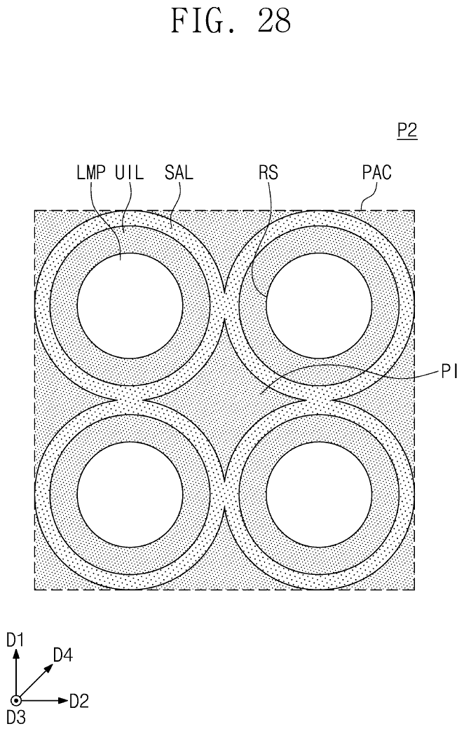

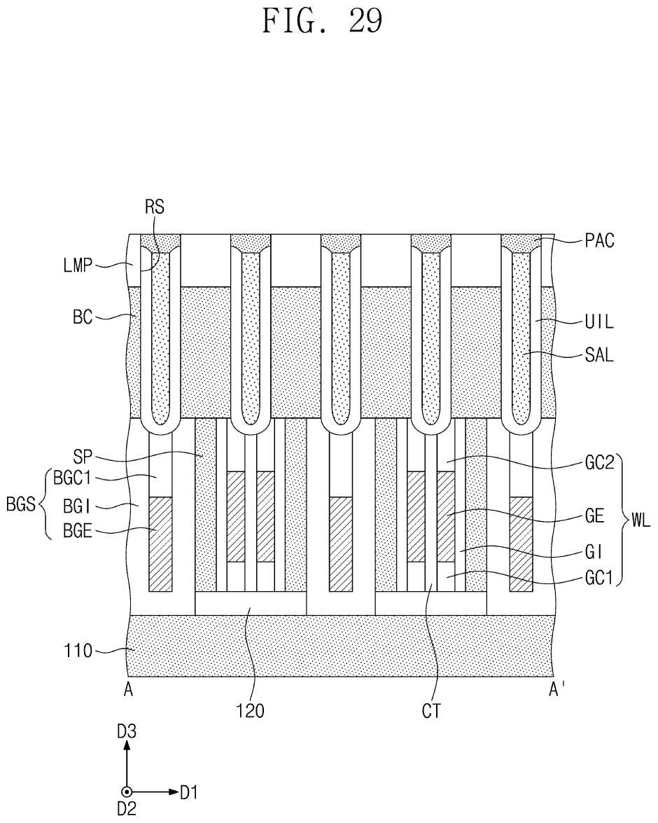

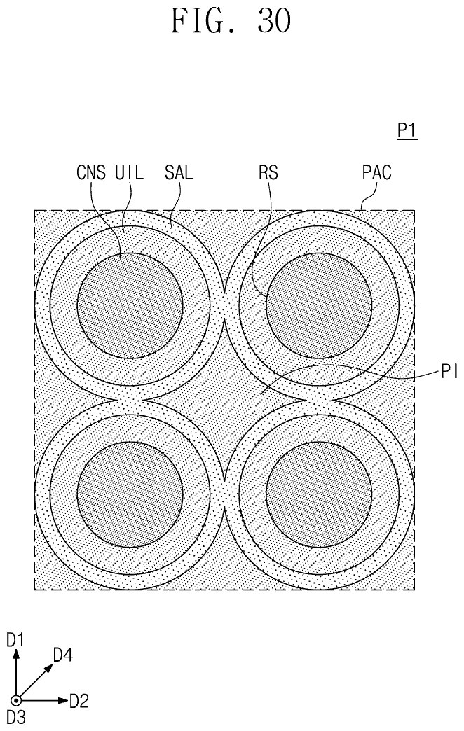

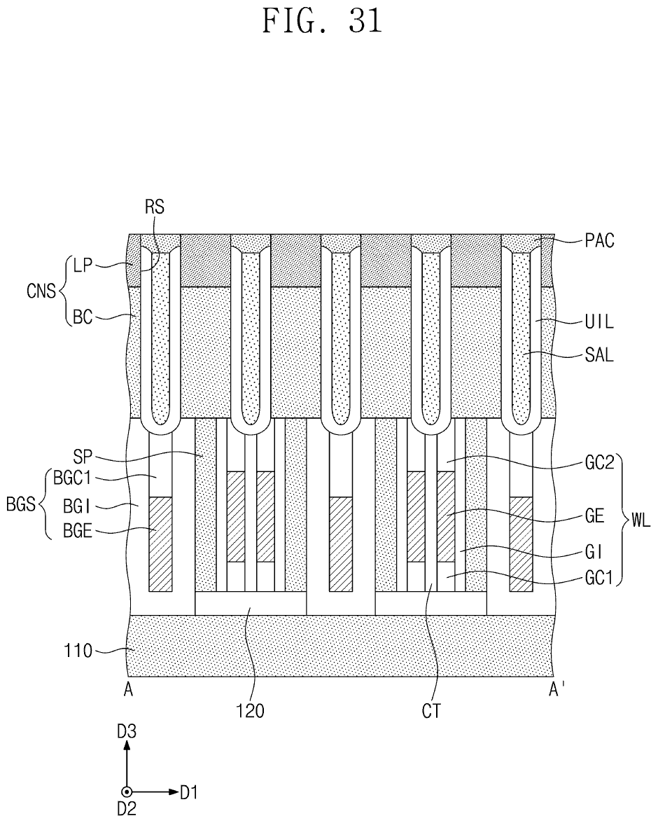

FIGS. 27 to 31 are diagrams illustrating a method for manufacturing a semiconductor device according to some embodiments of the inventive concept. Specifically, FIG. 27 is a plan view illustrating a semiconductor device according to some embodiments of the inventive concept. FIG. 28 is an enlarged view taken along portion ‘P2’ of FIG. 27. FIG. 29 is a cross-sectional view taken along line A-A′ of FIG. 27. FIG. 30 is an enlarged view taken along portion ‘P1’ of FIG. 4. FIG. 31 is a cross-sectional view taken along line A-A′ of FIG. 4.

Referring to FIGS. 27, 28, and 29, the process of forming a connection structure CNS described with reference to FIGS. 4, 22, 23A, and 23B may be performed in another manner.

The storage node contact BC and a landing mold pattern LMP may be sequentially formed on the semiconductor pattern SP. Thereafter, the upper insulating layer UIL, the sacrificial film SAL, the pillar pattern PI, and a preliminary capping pattern PAC may be sequentially formed in the recess RS.

Referring to FIGS. 4, 30, and 31, the landing mold pattern LMP described with reference to FIGS. 27, 28, and 29 may be removed. The landing pad LP may be formed in a region in which the landing mold pattern LMP is removed. In other words, the storage node contact BC may be formed through an embossing process, but the landing pad LP may be formed through an engraving process unlike what is described with reference to FIGS. 4, 22, 23A, and 23B.

Referring back to FIGS. 4, 5, and 6A to 6C, the preliminary capping pattern PAC may be removed. Thereafter, the semiconductor device described with reference to FIGS. 4, 5, and 6A to 6C may be formed using the method for manufacturing a semiconductor device described above.

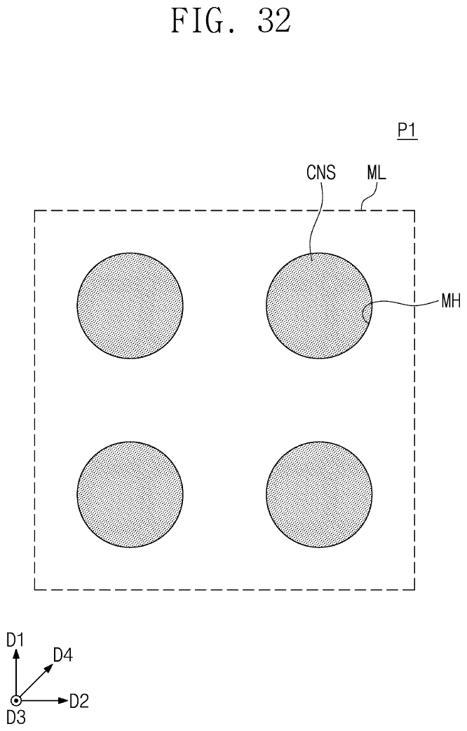

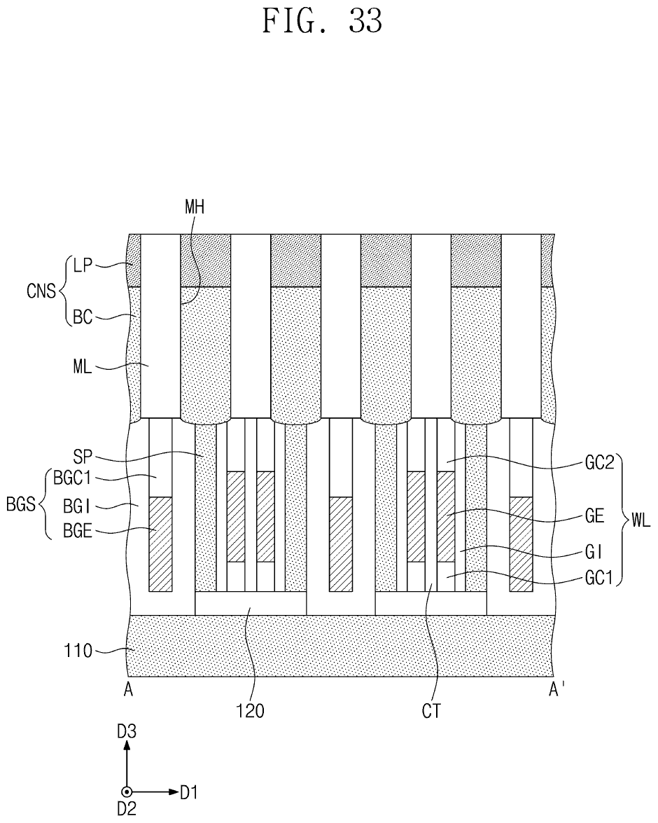

FIGS. 32 and 33 are diagrams illustrating a method for manufacturing a semiconductor device according to some embodiments of the inventive concept. Specifically, FIG. 32 is an enlarged view taken along portion ‘P1’ of FIG. 4. FIG. 33 is a cross-sectional view taken along line A-A′ of FIG. 4.

Referring to FIGS. 4, 32, and 33, the connection structure CNS described with reference to FIGS. 4, 22, 23A, and 23B may be formed through the engraving process.

A mold film ML may be formed on a front side of the first substrate 110. Mold holes MH may be formed inside the mold film ML through a process of removing the mold film ML. The connection structures CNS may be formed in the mold holes MH.

Referring back to FIGS. 4, and 7, the mold film ML described with reference to FIGS. 4, 32, and 33 may be removed. Thereafter, the semiconductor device described with reference to FIGS. 4 and 7 may be formed using the method for manufacturing a semiconductor device described above.

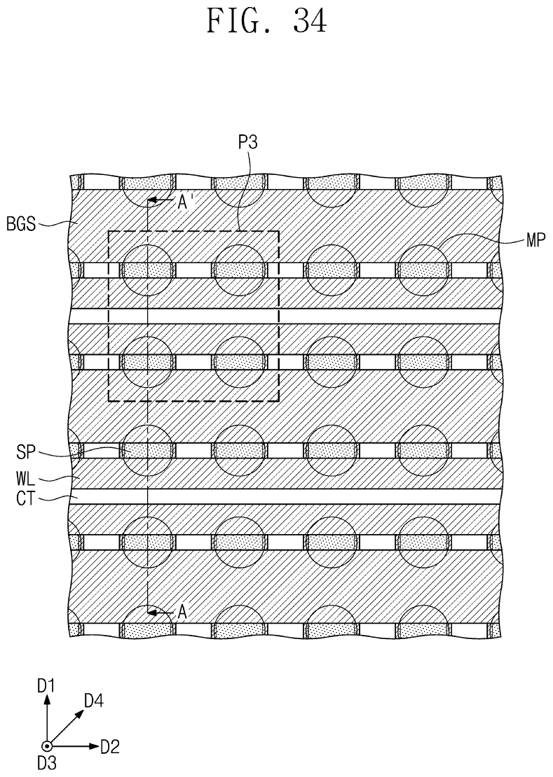

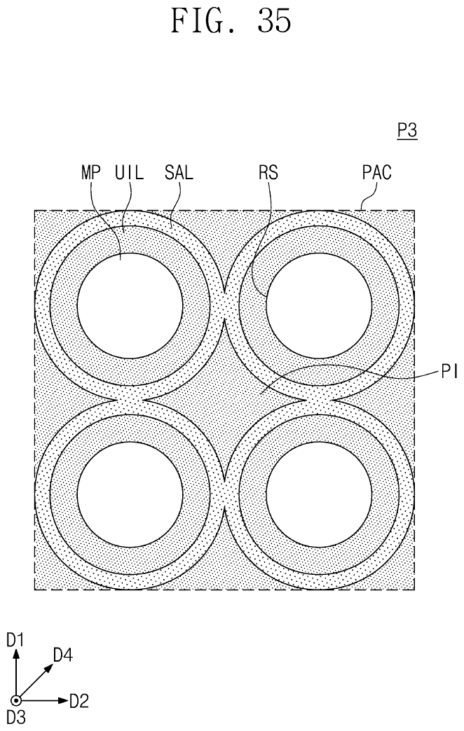

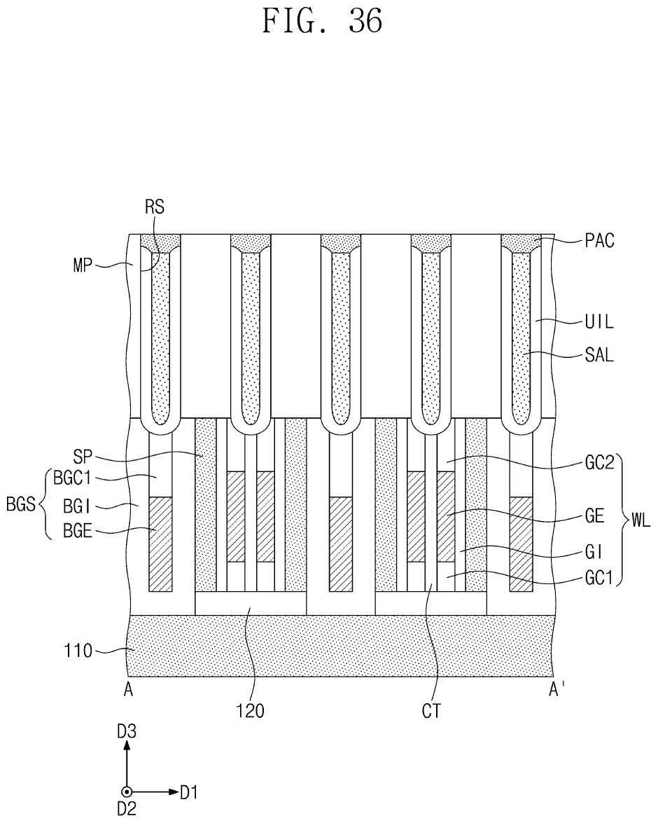

FIGS. 34 to 36 are diagrams illustrating a method for manufacturing a semiconductor device according to some embodiments of the inventive concept. Specifically, FIG. 34 is a plan view illustrating a semiconductor device according to some embodiments of the inventive concept. FIG. 35 is an enlarged view taken along portion ‘P3’ of FIG. 34. FIG. 36 is a cross-sectional view taken along line A-A′ of FIG. 34.

Referring to FIGS. 34 to 36, the connection structure CNS described with reference to FIGS. 4, 22, 23A, and 23B may be formed through an engraving process.

A mold film (not shown) may be formed on the front side of the first substrate 110. Mold patterns MP disposed spaced apart from each other may be formed through the process of removing the mold film ML. The recess RS may be defined between the mold patterns MP. The upper insulating layer UIL, the sacrificial film SAL, the pillar pattern PI, and the preliminary capping pattern PAC may be sequentially formed in the recess RS.

Referring back to FIGS. 4, 5, and 6A to 6C, the mold patterns MP described with reference to FIGS. 34 to 36 may be removed. The connection structures CNS may be formed in a region in which the mold patterns MP are removed. The preliminary capping pattern PAC may be removed. Thereafter, the semiconductor device described with reference to FIGS. 4, 5, and 6A to 6C may be formed using the method for manufacturing a semiconductor device described above.

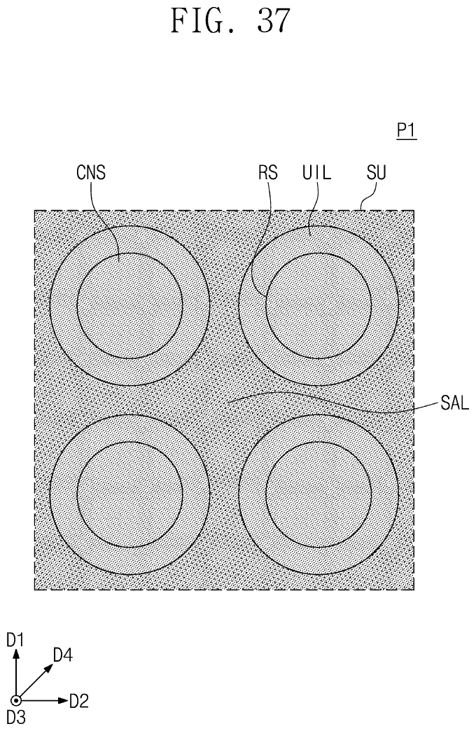

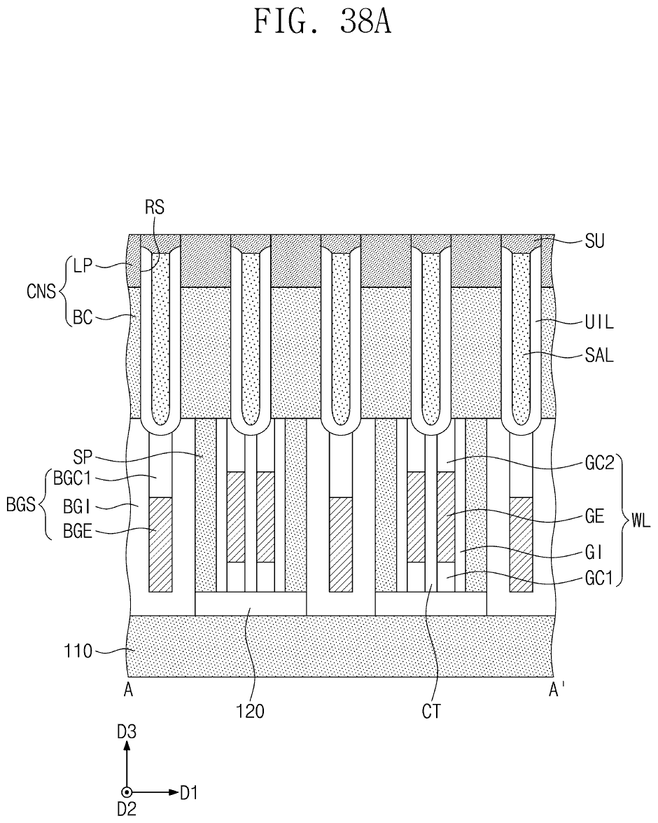

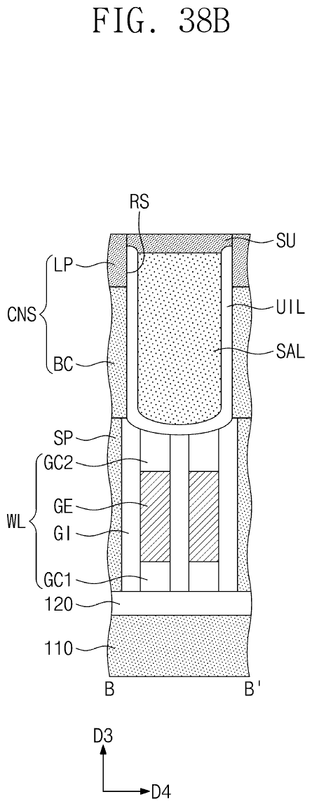

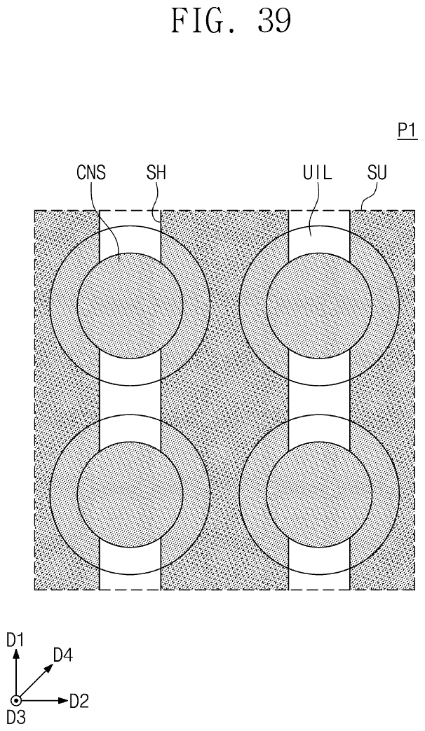

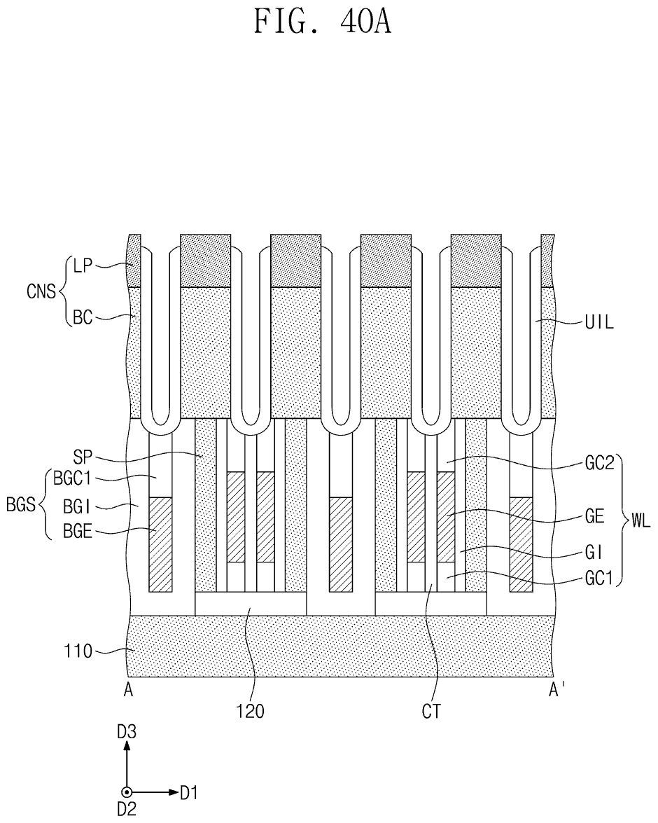

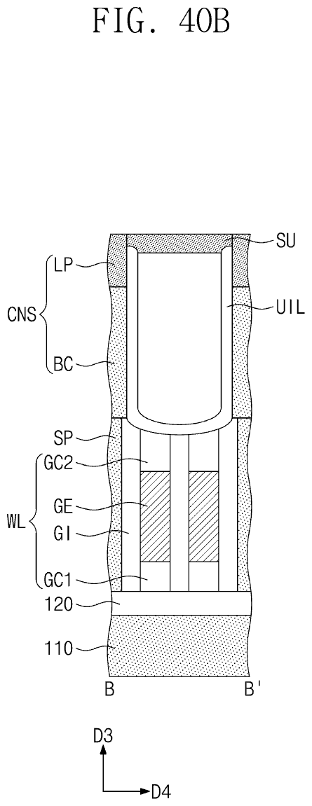

FIGS. 37 to 40B are diagrams illustrating a method for manufacturing a semiconductor device according to some embodiments of the inventive concept. Specifically, FIGS. 37 and 39 are enlarged views each taken along portion ‘P1’ of FIG. 4. FIGS. 38A and 40A are cross-sectional views each taken along line A-A′ of FIG. 4. FIGS. 38B and 40B are cross-sectional views each taken along line B-B′ of FIG. 4.

Referring to FIGS. 4, 37, 38A and 38B, a process of removing an upper portion of each of the upper insulating layer UIL and the sacrificial film SAL may be performed after a process of forming the sacrificial film SAL described with reference to FIGS. 4, 22, 23A and 23B. Thereafter, the support pattern SU may be formed to be on and at least partially cover an upper surface of each of the upper insulating layer UIL and the sacrificial film SAL.

Referring to FIGS. 4, 39, 40A and 40B, support holes SH may be formed through a process of partially removing the support pattern SU. The sacrificial film SAL may be exposed by the support holes SH. The exposed sacrificial film SAL may be removed using the support holes SH as paths. Accordingly, a region exposed to the outside, and not filled with a solid material may be formed between the connection structures CNS.

Referring back to FIGS. 11 to 14, the capping pattern AC may be formed in the region in which the support pattern SU is partially removed. Accordingly, the air gap AG may be formed between the connection structures CNS. Thereafter, the semiconductor device described with reference to FIGS. 11 to 12B, and the semiconductor device described with reference to FIGS. 13 and 14 may be formed using the method for manufacturing a semiconductor device described above.

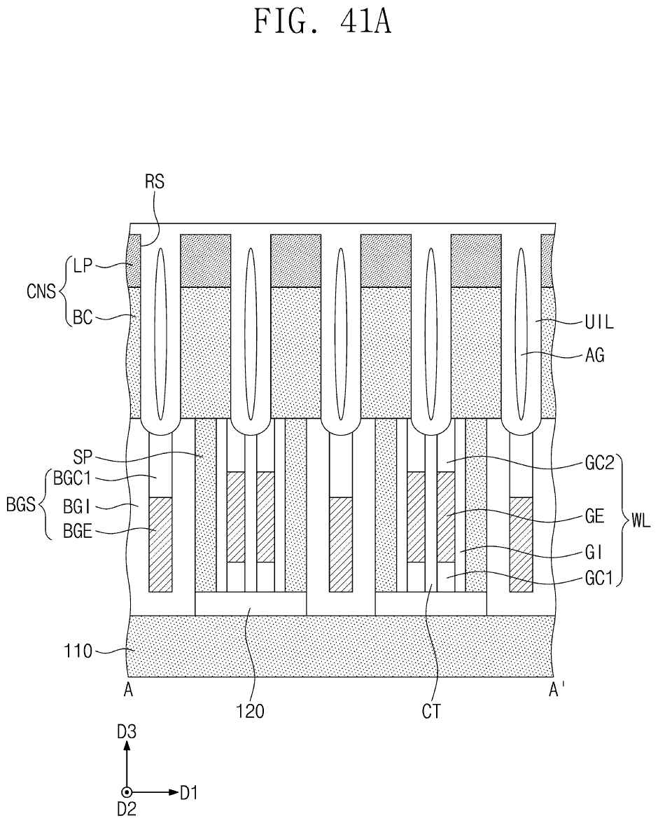

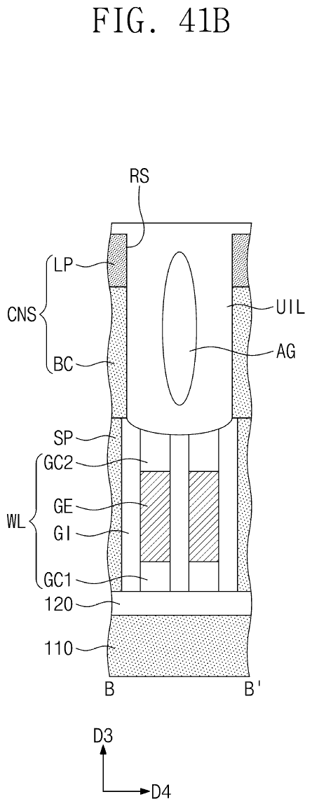

FIGS. 41A and 41B are diagrams illustrating a method for manufacturing a semiconductor device according to some embodiments of the inventive concept. Specifically, FIG. 41A is a cross-sectional view taken along line A-A′ of FIG. 4. FIG. 41B is a cross-sectional view taken along line B-B′ of FIG. 4.

Referring to FIGS. 4, 41A and 41B, the upper insulating layer UIL may be formed to at least partially surround the connection structures CNS. When the upper insulating layer UIL is formed, the air gap AG may be formed inside the upper insulating layer UIL. A process of forming each of the sacrificial film SAL, the pillar pattern PI and the capping pattern AC may be omitted. Thereafter, the semiconductor device described with reference to FIGS. 4, 15, 16A and 16B may be formed using the method for manufacturing a semiconductor device described above.

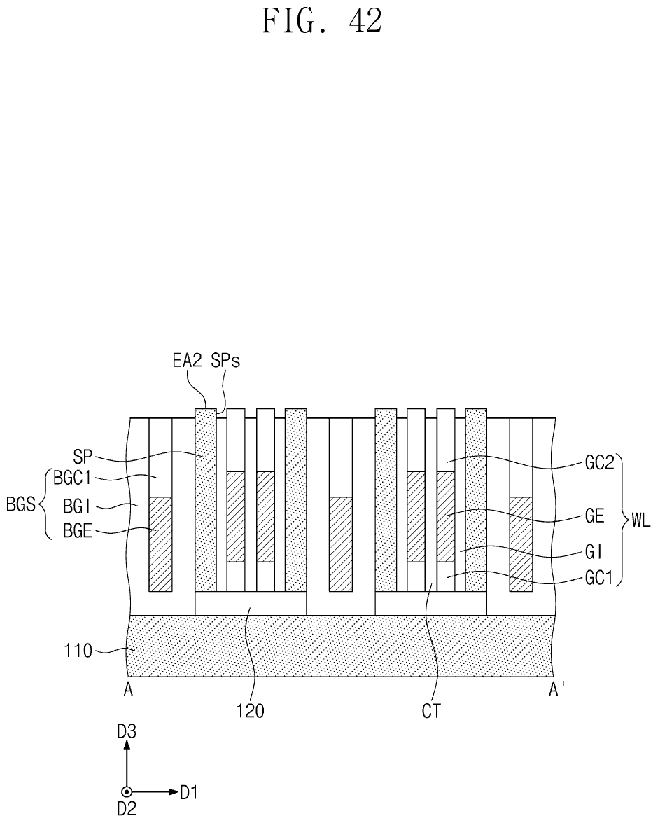

FIG. 42 is a diagram illustrating a method for manufacturing a semiconductor device according to some embodiments of the inventive concept. Specifically, FIG. 42 is a cross-sectional view taken along line A-A′ of FIG. 4.

Referring to FIGS. 4 and 42, a process of removing an upper portion of each of the back-gate insulating pattern BGI, the first back-gate capping pattern BGC1, the gate insulating pattern GI, the second gate capping pattern GC2, and the interlayer insulating layer ILD (see FIG. 6C) may be performed before a process of forming the connection structure CNS described with reference to FIGS. 22, 23A, and 23B. Accordingly, the second edge portion EA2 of the semiconductor pattern SP may be located at a higher level than an upper surface of each of the back-gate insulating pattern BGI, the first back-gate capping pattern BGC1, the gate insulating pattern GI, the second gate capping pattern GC2, and the interlayer insulating layer ILD (see FIG. 6C). Side surfaces SPs of the semiconductor pattern SP may be partially exposed.

Thereafter, the semiconductor device described with reference to FIGS. 4, 17A and 17B may be formed using the method for manufacturing a semiconductor device described above.

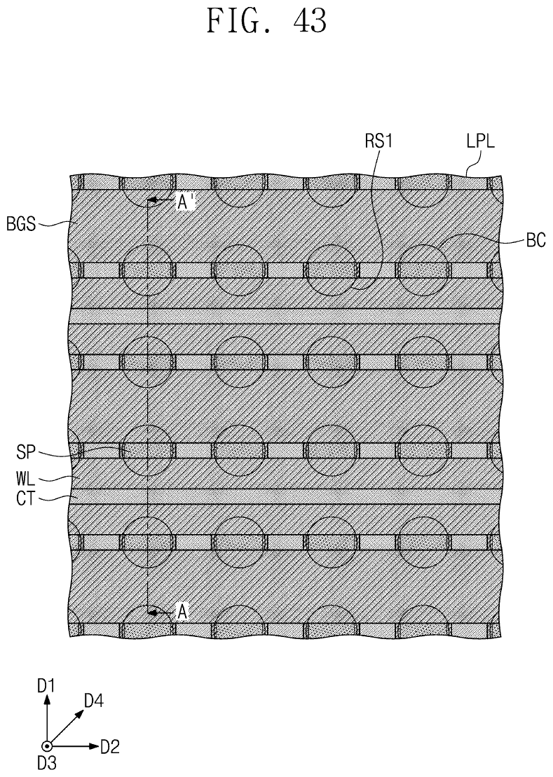

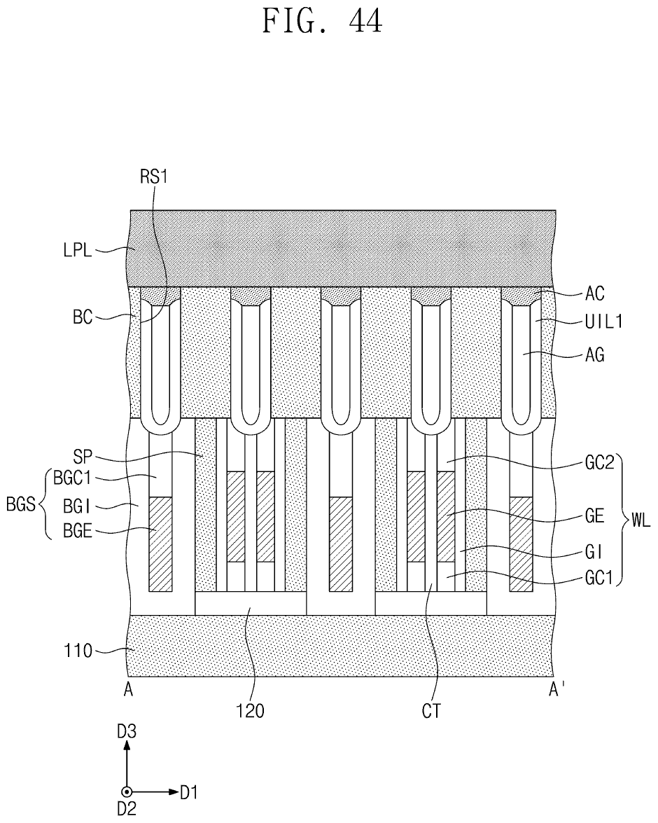

FIGS. 43 and 44 are diagrams illustrating a method for manufacturing a semiconductor device according to some embodiments of the inventive concept. FIG. 43 is a plan view illustrating a semiconductor device according to some embodiments of the inventive concept. FIG. 44 is a cross-sectional view taken along line A-A′ of FIG. 43.

Referring to FIGS. 43 and 44, a storage node contact film (not shown) may be formed on the semiconductor pattern SP before the process of forming the connection structure CNS described with reference to FIGS. 22, 23A, and 23B. A process of partially removing the storage node contact film may be performed, and thus the storage node contact film may be divided into a plurality of storage node contacts BC. The first recess RS1 may be formed between the storage node contacts BC through the removing process.

The upper insulating layer UIL and the capping pattern AC may be formed in the first recess RS1. The air gap AG may be formed between the storage node contacts BC. Thereafter, a landing pad film LPL may be formed on the front side of the first substrate 110.

Referring back to FIGS. 18 and 19A to 19C, a process of partially removing the landing pad film LPL described with reference to FIGS. 43 and 44 may be performed, and thus a second recess RS2 may be formed. As in FIG. 19A, a second upper insulating layer UIL2 may be formed in the second recess RS2. As in FIG. 19B, the second upper insulating layer UIL2 and a third upper insulating layer UIL3 may be sequentially formed in the second recess RS2. As in FIG. 19C, the first upper insulating layer UIL1, the capping pattern AC and the second air gap AG may be formed.

Thereafter, the semiconductor device described with reference to FIGS. 18, 19A to 19C may be formed using the method for manufacturing a semiconductor device described above.

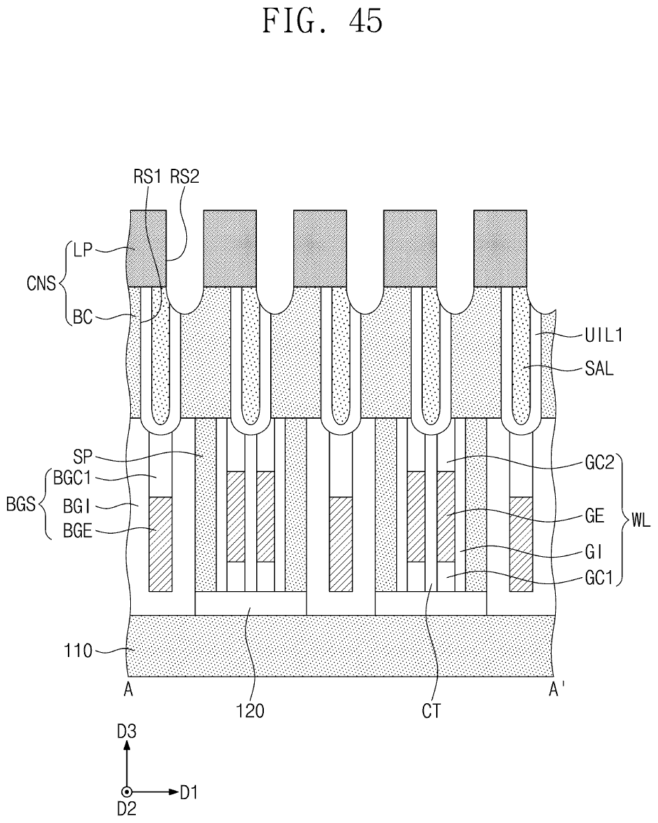

FIG. 45 is a diagram illustrating a method for manufacturing a semiconductor device according to some embodiments of the inventive concept. FIG. 45 is a cross-sectional view taken along line A-A′ of FIG. 18.

Referring to FIGS. 18 and 45, the first upper insulating layer UIL1 and the sacrificial film SAL may be sequentially formed in the first recess RS1 after the process of forming the first recess RS1 described with reference to FIGS. 43 and 44.

Thereafter, the landing pad film (not shown) may be formed on the first substrate 110. A process of partially removing the landing pad film may be performed, and thus the second recess RS2 may be formed. The sacrificial film SAL may be exposed through the second recess RS2. Thereafter, the exposed sacrificial film SAL may be removed using the second recess RS2 as a path.

Thereafter, the semiconductor device described with reference to FIGS. 18 and 20 may be formed using the method for manufacturing a semiconductor device described above.

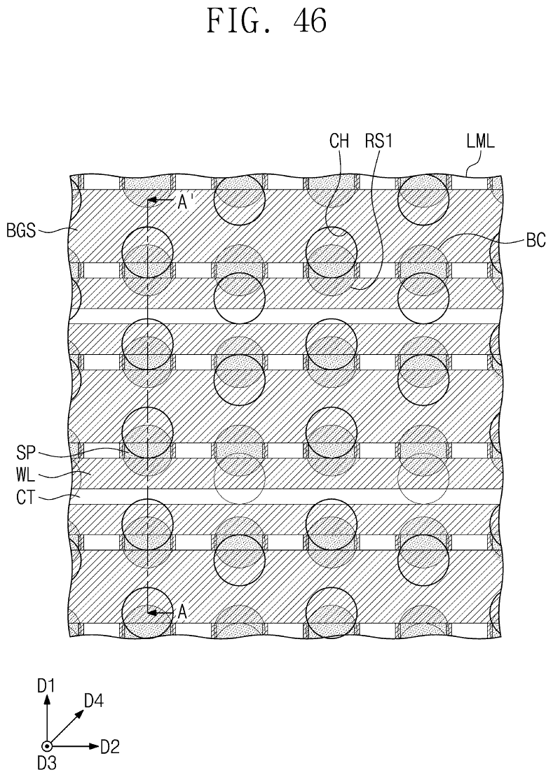

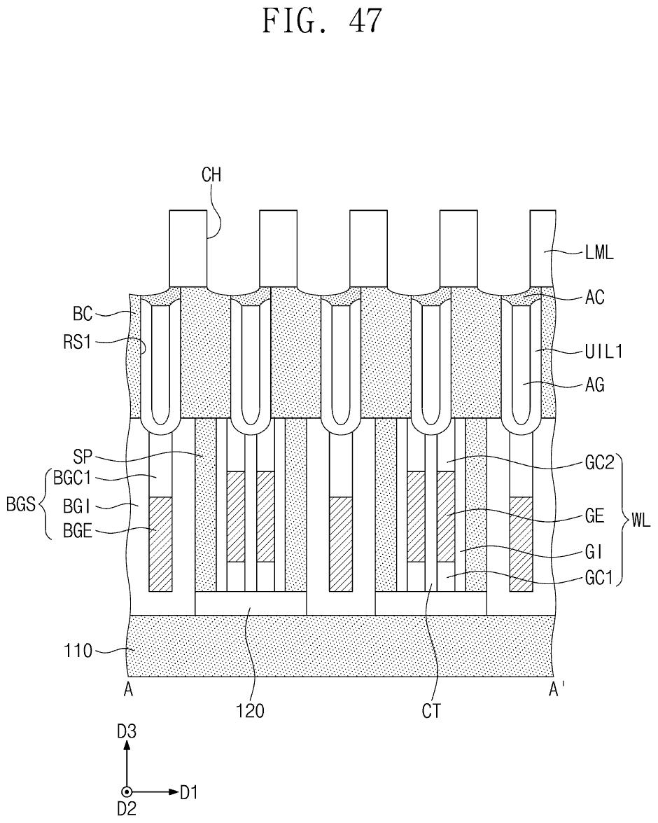

FIGS. 46 and 47 are diagrams illustrating a method for manufacturing a semiconductor device according to some embodiments of the inventive concept. FIG. 46 is a plan view illustrating a semiconductor device according to some embodiments of the inventive concept. FIG. 47 is a cross-sectional view taken along line A-A′ of FIG. 46.

Referring to FIGS. 46 and 47, the landing pad LP described with reference to FIG. 21 may be formed through an engraving process. After the process of forming the capping pattern AC described with reference to FIGS. 43 and 44, a landing mold film LML may be formed on the front side of the first substrate 110. A process of partially removing the landing mold film LML may be performed. Accordingly, contact holes CH may be formed inside the landing mold film LML.

Referring to FIGS. 18 and 21, the landing mold film LML described with reference to FIGS. 46 and 47 may be referred to as the second upper insulating layer UIL2. The landing pads LP may be formed to at least partially fill the insides of the contact holes CH.

Thereafter, the semiconductor device described with reference to FIGS. 18 and 21 may be formed using the method for manufacturing a semiconductor device described above.

According to the inventive concept, an air gap may be interposed between connection structures. Accordingly, using the air gap in which a space between the connection structures is not filled and remains empty may reduce capacitance unnecessarily formed between the adjacent connection structures compared to completely filling the space between the connection structures with an insulating material. As a result, disturbance caused by the adjacent connection structures may be reduced. Accordingly, electrical characteristics of a semiconductor device may be improved.

In addition, the air gap may be interposed between the connection structures so that a smaller separation distance between the connection structures may be formed compared to completely filling the space between the connection structures with an insulating material. Accordingly, a width of the connection structure may be more widely formed, and a contact area between the connection structure and a semiconductor pattern may be increased. As a result, electrical characteristics of the semiconductor device may be improved.

The above description of embodiments of the inventive concept provides an example for description of the inventive concept. Therefore, the inventive concept is not limited to the above embodiments, and it is obvious that various modifications and changes such as combining the above embodiments may be made by those skilled in the art within the technical spirit of the inventive concept.

What is claimed is:

1. A semiconductor device comprising:
a substrate;
a bit line on the substrate extending in a first direction parallel to an upper surface of the substrate;
a first semiconductor pattern and a second semiconductor pattern on the bit line, each extending in a second direction perpendicular to the first direction, and spaced apart from each other in the first direction;
a word line between the first semiconductor pattern and the second semiconductor pattern extending in the second direction;
a first connection structure on one end portion of the first semiconductor pattern;
a second connection structure on one end portion of the second semiconductor pattern;
a data storage pattern on each of the first connection structure and the second connection structure; and
a gap between the first connection structure and the second connection structure.

2. The semiconductor device of claim 1, wherein the gap surrounds each of the first connection structure and the second connection structure in a plan view of the semiconductor device.

3. The semiconductor device of claim 1, further comprising a capping pattern on a side surface of the first connection structure,
wherein a lower surface of the capping pattern is exposed to the gap.

4. The semiconductor device of claim 1, further comprising a capping pattern on a side surface of an upper portion of the first connection structure,
wherein the gap is located under the capping pattern.

5. The semiconductor device of claim 1, further comprising a capping pattern on a side surface of the first connection structure,
wherein the gap is between the capping pattern and the word line.

6. The semiconductor device of claim 1, further comprising an upper insulating layer on a side surface of the first connection structure,
wherein the upper insulating layer is between the gap and the first connection structure.

7. The semiconductor device of claim 6, wherein a surface of the upper insulating layer is directly on and flush with the side surface of the first connection structure.

8. The semiconductor device of claim 1, further comprising:
a third semiconductor pattern spaced apart from the second semiconductor pattern in the second direction;
a third connection structure on the third semiconductor pattern; and
a pillar pattern between the first connection structure and the third connection structure,
wherein the gap is between the first connection structure and the pillar pattern.

9. The semiconductor device of claim 8, wherein the gap at least partially surrounds the pillar pattern.

10. The semiconductor device of claim 8, further comprising a capping pattern on a side surface of the first connection structure,
wherein the capping pattern is on an upper surface of the pillar pattern.

11. The semiconductor device of claim 8, further comprising:
an upper insulating layer on a side surface of the first connection structure; and
a capping pattern on an upper surface of each of the upper insulating layer and the pillar pattern,
wherein the gap is between the pillar pattern and the upper insulating layer.

12. The semiconductor device of claim 1, wherein a width of the gap decreases as a distance to the substrate decreases.

13. A semiconductor device comprising:
a substrate;
a bit line on the substrate extending in a first direction parallel to an upper surface of the substrate;
a semiconductor pattern on the bit line extending in a second direction perpendicular to the first direction;
a word line on side surfaces of the semiconductor pattern extending in a third direction parallel to the upper surface of the substrate, and perpendicular to first direction;
a data storage pattern on one end portion of the semiconductor pattern;
a connection structure between the one end portion of the semiconductor pattern and the data storage pattern; and
a gap at least partially surrounding a side surface of the connection structure.

14. The semiconductor device of claim 13, further comprising a capping pattern on the side surface of the connection structure,
wherein a lower surface of the capping pattern is exposed to the gap.

15. The semiconductor device of claim 13, further comprising a capping pattern on the side surface of the connection structure,
wherein the gap is between the capping pattern and the word line.

16. The semiconductor device of claim 13, further comprising a pillar pattern on the side surface of the connection structure,
wherein the gap is between the connection structure and the pillar pattern.

17. The semiconductor device of claim 16, further comprising:
an upper insulating layer on the side surface of the connection structure; and
a capping pattern on an upper surface of each of the upper insulating layer and the pillar pattern,
wherein the gap is between the upper insulating layer and the pillar pattern.

18. The semiconductor device of claim 13, further comprising an upper insulating layer directly on and flush with the side surface of the connection structure,
wherein the upper insulating layer is between the gap and the connection structure.

19. The semiconductor device of claim 13, wherein a width of the gap decreases as a distance to the substrate decreases.

20. A semiconductor device comprising:
a substrate;
a bit line on the substrate extending in a first direction parallel to an upper surface of the substrate;
a first semiconductor pattern and a second semiconductor pattern on the bit line, each extending in a second direction perpendicular to the first direction, and spaced apart from each other in the first direction;
a bit line contact between each of the first semiconductor pattern and the second semiconductor pattern, and the bit line;
a first gate electrode extending between the first semiconductor pattern and the second semiconductor pattern in a third direction parallel to the upper surface of the substrate, and perpendicular to the first direction;
a second gate electrode spaced apart from the first gate electrode in the first direction with the first semiconductor pattern therebetween, an upper surface of the second gate electrode being located closer to the substrate than an upper surface of the first gate electrode;
a first connection structure on one end portion of the first semiconductor pattern;
a second connection structure on one end portion of the second semiconductor pattern;
a data storage pattern on each of the first connection structure and the second connection structure; and
a gap between the first connection structure and the second connection structure.
